(19) United States
(12) Patent Application Publication
(10) Pub. No.: US 2026/0280421 A1
(43) Pub. Date: Sep. 17, 2026

(54) POWER CONVERSION DEVICE

(71) Applicant: MITSUBISHI ELECTRIC CORPORATION, Chiyoda-ku, Tokyo (JP)

(72) Inventors: Hiroshi IKARASHI, Chiyoda-ku, Tokyo (JP); Yuji SHIRAKATA, Chiyoda-ku, Tokyo (JP); Hiroyuki YAHARA, Chiyoda-ku, Tokyo (JP); Tomohito FUKUDA, Chiyoda-ku, Tokyo (JP); Naoki TAKIGAWA, Chiyoda-ku, Tokyo (JP)

(73) Assignee: MITSUBISHI ELECTRIC CORPORATION, Chiyoda-ku, Tokyo (JP)

(21) Appl. No.: 19/472,854

(22) PCT Filed: Apr. 2, 2024
(86) PCT No.: PCT/JP2024/013636

§ 371 Date: Oct. 6, 2025

(30) Foreign Application Priority Data
Apr. 28, 2023 (JP) 2023-074109

(51) Int. Cl. H02M 3/00; H02M 3/335; H05K 7/20

(52) U.S. Cl. CPC H02M 3/003; H02M 3/33573; H05K 7/209

(57) ABSTRACT

The power conversion device includes a power unit. The power unit includes: a substrate which has a first surface and a second surface; a first heat radiation member which has a third surface thermally connected to the first surface; and a first heat transfer member which includes a first portion disposed inside the first heat radiation member and a second portion connected to the first portion and disposed outside the first heat radiation member, and is configured to transfer heat from the first portion to the second portion. A first electronic component is mounted on the first surface of the substrate. The first portion of the first heat transfer member is thermally connected to the first electronic component via the first heat radiation member.

### TECHNICAL FIELD

The present disclosure relates to a power conversion device.

### BACKGROUND ART

In recent years, due to an increasing demand to make a power conversion device smaller in size and higher in output, the heat generation density of electronic components (circuit components) mounted on the power conversion device has increased. In order to prevent the temperature of electronic components from exceeding an allowable temperature due to heat generation, there is a strong need to improve heat radiation of the power conversion device. In other words, in order to make the power conversion device smaller in size and higher in output, it is necessary to improve heat radiation of the power conversion device.

Generally, in order to prevent the temperature of the electronic component from rising, a power conversion device includes a heat radiation member (cooler) configured to radiate heat generated in an electronic component to the outside.

The power conversion device described in Japanese U.S. Pat. No. 6,158,051 (PTL 1) includes a heat radiation base and a power supply circuit, wherein the heat radiation base includes a base portion and a vertical portion, one surface of the base portion faces a flow path of a cooling refrigerant, the vertical portion is formed on the other surface of the base portion opposite to the one surface, and the power supply circuit is mounted on the vertical portion.

### CITATION LIST

### Patent Literature

PTL 1: Japanese U.S. Pat. No. 6,158,051

### SUMMARY OF INVENTION

### Technical Problem

However, in the power conversion device described in PTL 1, it is necessary to mount the electronic components that generate a large amount of heat on a part of the vertical portion that is connected to the base portion. This is because that in the heat radiation base described in PTL 1, the heat radiation of the electronic components decreases as the part of the vertical portion on which the electronic components are mounted becomes further away from the base portion.

Therefore, in the power conversion device described in PTL 1, in order to achieve high output, it is necessary to provide a longer connection region that is connected to the base portion in the vertical portion so as to mount a large number of electronic components that generate a large amount of heat near the base portion, and thereby it is difficult to make the power conversion device smaller in size. In addition, when a relatively large electronic component that generates a large amount of heat (for example, a relatively large package that includes a large number of electronic components) is mounted near the base portion, it is also necessary to provide the connection region longer so that the longitudinal direction of the electronic component is the same as that of the longer connection region.

A main object of the present disclosure is to provide a power conversion device which is smaller in size and higher in output.

### Solution to Problem

A power conversion device according to the present disclosure includes at least one power unit. The at least one power unit includes: a substrate which has a first surface and a second surface opposite to the first surface; a first heat radiation member which has a third surface thermally connected to the first surface or the second surface; and at least one first heat transfer member which includes a first portion disposed inside the first heat radiation member and a second portion connected to the first portion and disposed outside the first heat radiation member, and is configured to transfer heat from the first portion to the second portion. At least one first electronic component is mounted on at least one of the first surface and the second surface of the substrate.

The first portion of the at least one first heat transfer member is thermally connected to the at least one first electronic component via the first heat radiation member.

### Advantageous Effects of Invention

According to the present disclosure, it is possible to provide a power conversion device which is smaller in size and higher in output.

### BRIEF DESCRIPTION OF DRAWINGS

FIG. 1 is a circuit diagram illustrating a power supply circuit included in a power conversion device according to an embodiment of the present disclosure.

FIG. 2 is a perspective view illustrating a power unit and a cooler included in the power conversion device according to a first embodiment of the present disclosure.

FIG. 3 is a plan view illustrating a wiring pattern which is formed on a substrate of the power conversion device in FIG. 2 and constitutes a part of the power supply circuit in FIG. 1.

FIG. 4 is an exploded perspective view illustrating the power unit included in the power conversion device in FIG. 2.

FIG. 5 is a front view illustrating the power unit included in the power conversion device in FIG. 2.

FIG. 6 is a perspective view illustrating a transformer included in the power unit of the power conversion device in FIG. 2.

FIG. 7 is a cross-sectional view taken along line VII-VII in FIG. 6.

FIG. 8 is a perspective view illustrating a power unit included in a power conversion device according to a second embodiment.

FIG. 9 is an exploded perspective view illustrating the power unit included in the power conversion device in FIG. 8.

FIG. 10 is a cross-sectional view illustrating the power unit included in the power conversion device in FIG. 8.

FIG. 11 is a circuit diagram illustrating a plurality of power supply circuits included in a power conversion device according to a third embodiment.

FIG. 12 is a perspective view illustrating a power unit and a cooler included in the power conversion device according to the third embodiment.

FIG. 13 is an exploded perspective view illustrating the power unit in FIG. 12.

FIG. 14 is a side view illustrating a structure of the power unit in FIG. 12 and a connection structure between the power unit and the cooler.

FIG. 15 is a cross-sectional view illustrating the power unit in FIG. 12.

FIG. 16 is a perspective view illustrating a plurality of power units, a cooler, and a housing included in the power conversion device according to the third embodiment in such a state that a side plate of the housing is opened.

FIG. 17 is a perspective view illustrating the housing in FIG. 16 viewed from a different direction of FIG. 16.

FIG. 18 is an exploded perspective view illustrating a power unit included in a power conversion device according to a fourth embodiment.

FIG. 19 is a cross-sectional view illustrating the power unit in FIG. 18.

FIG. 20 is a cross-sectional view illustrating a first modification of the power unit included in the power conversion device according to the fourth embodiment.

FIG. 21 is an exploded perspective view illustrating a second modification of the power unit included in the power conversion device according to the fourth embodiment.

FIG. 22 is a cross-sectional view illustrating the power unit in FIG. 21.

FIG. 23 is a perspective view illustrating a power unit included in a power conversion device according to a fifth embodiment.

FIG. 24 is a cross-sectional view taken along line XXIV-XXIV in FIG. 23.

FIG. 25 is a perspective view illustrating a modification of a cooler included in the power conversion device according to the fifth embodiment.

FIG. 26 is a perspective view illustrating a power unit included in a power conversion device according to a sixth embodiment.

FIG. 27 is an exploded perspective view illustrating a first modification of the power unit included in the power conversion device according to the sixth embodiment.

FIG. 28 is an exploded perspective view illustrating a second modification of the power unit included in the power conversion device according to the sixth embodiment.

FIG. 29 is a perspective view illustrating a plurality of power units, a cooler, and a housing included in the power conversion device according to the sixth embodiment in such a state that a side plate of the housing is opened.

### DESCRIPTION OF EMBODIMENTS

Hereinafter, embodiments of the present disclosure will be described with reference to the drawings. In the following description, the same or corresponding portions will be denoted by the same reference numerals, and the description thereof will not be repeated.

### Configuration of Power Conversion Device and Power Supply Circuit

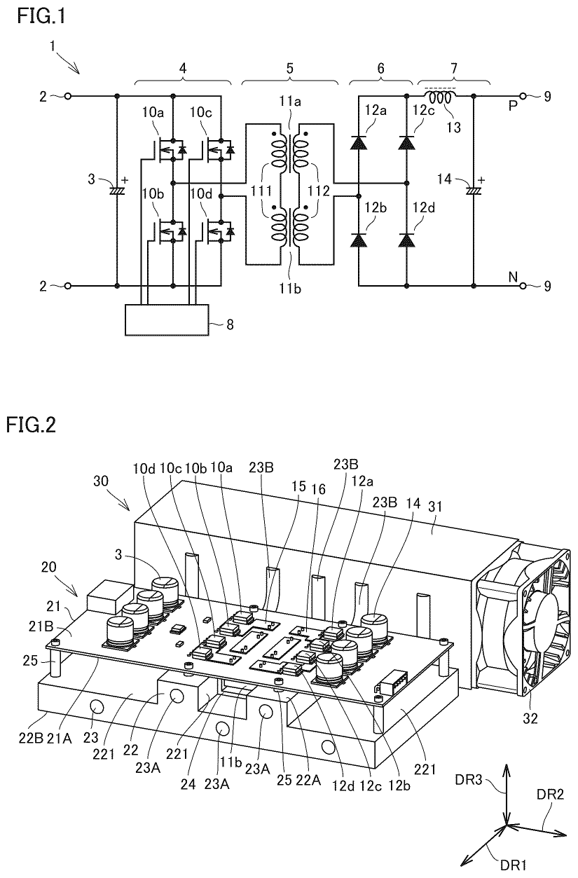

A power conversion device according to an embodiment of the present disclosure includes a power supply circuit. The power supply circuit is, for example, a DC-DC converter. FIG. 1 illustrates a circuit diagram of the DC-DC converter.

The application of the power conversion device according to an embodiment of the present disclosure is not particularly limited, and it may be applied to an electric vehicle, for example. The DC-DC converter is configured to, for example, convert an input voltage of about 100 V or more and 300 V or less supplied from a lithium ion battery into a voltage of about 12 V or more and 15 V or less and output the converted voltage so as to charge a lead storage battery.

As illustrated in FIG. 1, the DC-DC converter which serves as a power supply circuit 1 includes a pair of input terminals 2, an input capacitor 3, an inverter circuit 4, a transformer circuit 5, a rectifier circuit 6, a smoothing circuit 7, a control circuit 8, and a pair of output terminals 9. Inverter circuit 4 and a part of transformer circuit 5 constitute a primary circuit, and the remaining part of transformer circuit 5, rectifier circuit 6 and smoothing circuit 7 constitute a secondary circuit which operates at an operating voltage different from that of the primary circuit.

Inverter circuit 4 includes four switching elements 10a, 10b, 10c and 10d. The switching operation of the four switching elements 10a, 10b, 10c and 10d is controlled by control circuit 8. Each of the switching elements 10a, 10b, 10c and 10d is, for example, a power semiconductor element such as a MOS transistor (Metal Oxide Semiconductor Field Effect Transistor (MOSFET)) or an insulated gate bipolar transistor (IGBT). The semiconductor material of each of the switching elements 10a, 10b, 10c and 10d is not particularly limited, and includes, for example, silicon carbide (SiC).

Transformer circuit 5 is constituted by two transformers 11a and 11b, each of which includes a primary winding 111 and a secondary winding 112. Rectifier circuit 6 is constituted by four rectifier elements 12a, 12b, 12c and 12d. Each of the rectifier elements 12a, 12b, 12c and 12d is, for example, a power semiconductor element such as a diode, a MOS transistor, or a thyristor. Smoothing circuit 7 is constituted by a smoothing reactor 13 and a smoothing capacitor 14.

In the DC-DC converter which serves as power supply circuit 1, control circuit 8 controls the switching operation of each of the four switching elements 10a, 10b, 10c and 10d in inverter circuit 4 to convert a DC voltage input from the pair of input terminals 2 into an AC voltage. The AC voltage converted in inverter circuit 4 is converted into any AC voltage by transformers 11a and 11b included in transformer circuit 5. The AC voltage to be converted is determined by the winding ratio between primary winding 111 and secondary winding 112 in each of transformers 11a and 11b. Transformers 11a and 11b electrically insulate the pair of input terminal 2 from the pair of output terminals 9.

The AC voltage supplied from transformer circuit 5 is converted into a DC voltage again by the four rectifier elements 12a, 12b, 12c and 12d included in rectifier circuit 6. The DC voltage converted by rectifier circuit 6 is smoothed by smoothing reactor 13 and smoothing capacitor 14 included in smoothing circuit 7. Accordingly, the DC voltage output from the pair of output terminals 9 is stabilized. One potential of smoothing capacitor 14 is set as a reference potential of the power conversion device.

In power supply circuit 1 illustrated in FIG. 1, the semiconductor elements such as switching elements 10a, 10b, 10c and 10d, rectifier elements 12a to 12d, transformers 11a and 11b, and smoothing reactor 13 generate a relatively large amount of heat. Therefore, the power conversion device that includes power supply circuit 1 according to an embodiment of the present disclosure includes a heat radiation unit that radiates heat generated in at least one electronic component (first electronic component) of switching elements 10a, 10b, 10c and 10d, rectifier elements 12a to 12d, transformers 11a and 11b, and smoothing reactor 13 so as to keep the temperature of the first electronic component below an allowable temperature. The allowable temperature of each of the electronic components described above is, for example, 100° C. or more and 120° C. or less.

In the following first to fourth embodiments, the heat radiation unit of the power conversion device according to each embodiment of the present disclosure will be described in detail.

### First Embodiment

As illustrated in FIGS. 2 to 5, the power conversion device according to a first embodiment includes a power unit 20 and a cooler 30. Power unit 20 includes a substrate 21, a first heat radiation member 22, a plurality of first heat transfer members 23, a thermally conductive member 24, and a positioning member 25.

Substrate 21 is a circuit board that constitutes at least a part of power supply circuit 1. Substrate 21 has a first surface 21A and a second surface 21B opposite to first surface 21A. Hereinafter, for the convenience of description, a direction along first surface 21A is referred to as a first direction DR1. A direction along first surface 21A and orthogonal to the first direction is referred to as a second direction DR2. A direction orthogonal to first surface 21A is referred to as a third direction DR3.

Transformers 11a and 11b are mounted on first surface 21A. Switching elements 10a, 10b, 10c and 10d, rectifier elements 12a to 12d, and smoothing reactor 13 are mounted on second surface 21B. For example, input capacitor 3 and smoothing capacitor 14 are further mounted on second surface 21B. The capacitance of input capacitor 3 and smoothing capacitor 14 is preferably several tens of μF or more from the viewpoint of smoothing the input voltage or the output voltage. Each of input capacitor 3 and smoothing capacitor 14 is an electrolytic capacitor, for example.

Substrate 21 is formed with a wiring pattern for electrically connecting the electronic components included in power supply circuit 1. The wiring pattern is formed on each of first surface 21A and second surface 21B, for example. Substrate 21 is, for example, a glass composite substrate, a glass epoxy substrate, or a halogen-free substrate. The material of the wiring pattern may be any material with electrical conductivity, and may be, for example, copper.

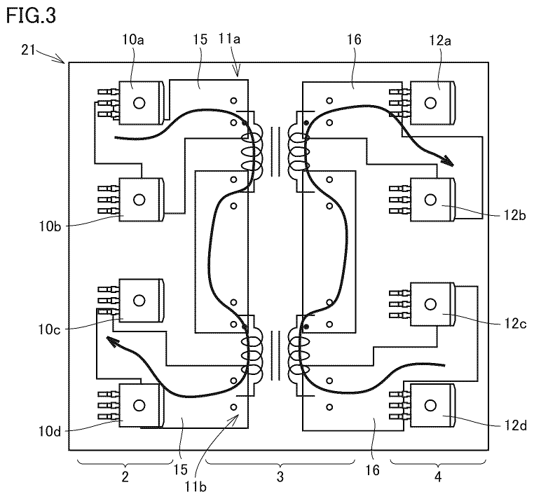

As illustrated in FIG. 3, substrate 21 is formed with a first wiring pattern 15 for electrically connecting inverter circuit 4 and primary winding 111 of transformers 11a and 11b included in transformer circuit 5, and a second wiring pattern 16 for electrically connecting rectifier circuit 6 and secondary winding 112 of transformers 11a and 11b. Each of first wiring pattern 15 and second wiring pattern 16 includes, for example, a portion formed on first surface 21A of substrate 21, a portion formed on second surface 21B, and a portion formed in a through hole that penetrates first surface 21A and second surface 21B and electrically connects the two portions mentioned above. Switching elements 10a, 10b, 10c and 10d included in inverter circuit 4 are disposed on one side of transformers 11a and 11b, and rectifier elements 12a, 12b, 12c and 12d included in rectifier circuit 6 are disposed on the other side of transformers 11a and 11b opposite to switching elements 10a, 10b, 10c and 10d. Switching elements 10a, 10b, 10c and 10d are arranged side by side in first direction DR1. Rectifier elements 12a, 12b, 12c and 12d are arranged side by side in first direction DR1. First wiring pattern 15 includes, for example, a portion disposed between switching element 10a and switching element 10b in first direction DR1 and a portion disposed between switching element 10c and switching element 10d in first direction DR1. Second wiring pattern 16 includes, for example, a portion disposed between rectifier element 12a and rectifier element 12b in first direction DR1 and a portion disposed between rectifier element 12c and rectifier element 12d in first direction DR1.

Preferably, each of first wiring pattern 15 and second wiring pattern 16 is designed to have a wide width so that the electrical resistance is low and excessive Joule heat is not generated during conduction. Preferably, each of first wiring pattern 15 and second wiring pattern 16 is designed to have a short length and a planar loop shape so that the parasitic inductance is low. Also, each of first wiring pattern 15 and second wiring pattern 16 is designed so that the distance (insulating distance) therebetween satisfies various safety standards.

Substrate 21 is positioned with respect to first heat radiation member 22 by a plurality of positioning members 25.

First heat radiation member 22 has a third surface 22A thermally connected to first surface 21A, and a fourth surface 22B opposite to the third surface. Third surface 22A is parallel to first surface 21A, for example. Third surface 22A is thermally connected to first surface 21A via, for example, thermally conductive member 24.

Third surface 22A may be in contact with first surface 21A. The material of first heat radiation member 22 may be any material having a high thermal conductivity, and includes, for example, aluminum (Al). The thermal conductivity of first heat radiation member 22 is 1.0 W/(m·K) or more, preferably 10.0 W/(m·K) or more, and more preferably 100.0 W/(m·K) or more. First heat radiation member 22 is obtained through extrusion, for example.

As illustrated in FIGS. 2 to 4, third surface 22A of first heat radiation member 22 is formed with a groove 221. Groove 221 has a pair of side surfaces 221A and a bottom surface 221B. The pair of side surfaces 221A is connected to third surface 22A. Each of the pair of side surfaces 221A is orthogonal to third surface 22A, for example. Bottom surface 221B is parallel to third surface 22A, for example.

As illustrated in FIGS. 2 to 4, a plurality of grooves 221 may be formed on third surface 22A of first heat radiation member 22, spaced apart from each other in second direction DR2. The depth of each of the plurality of grooves 221 may be equal to or different from each other. Each groove 221 is formed to extend from one end surface to the other end surface of first heat radiation member 22 in first direction DR1, for example.

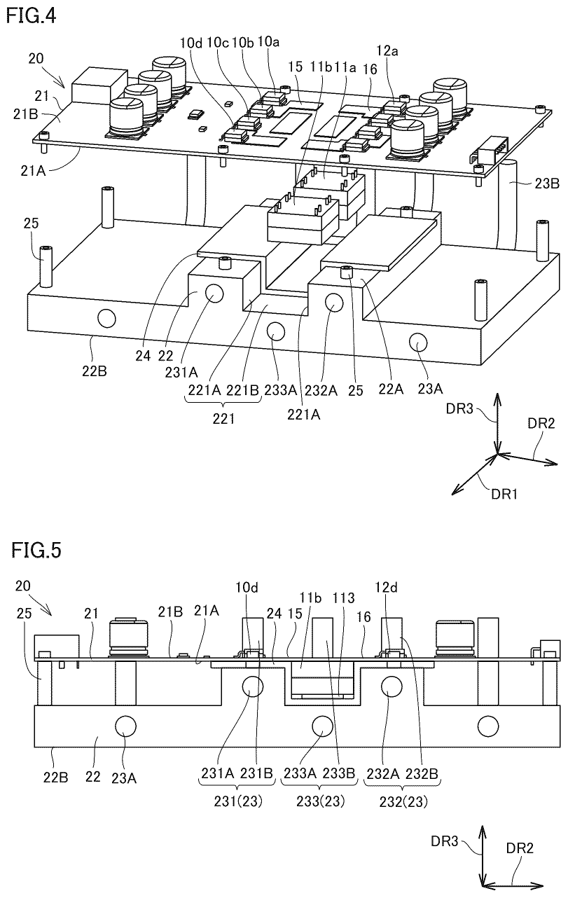

At least a part of transformer 11a or 11b is accommodated in groove 221. For example, all of transformer 11a or 11b and a part of thermally conductive member 24 are accommodated in groove 221. The pair of side surfaces 221A and bottom surface 221B of groove 221 are thermally connected to transformer 11a or 11b via thermally conductive member 24. The pair of side surfaces 221A are thermally connected to, for example, an outer peripheral surface of the core of transformer 11a or 11b. As illustrated in FIG. 4, bottom surface 221B is thermally connected to, for example, a spacer 113 of transformer 11a or 11b.

The plurality of first heat transfer members are separated from first heat radiation member 22. The thermal conductivity of each of the plurality of first heat transfer members 23 is higher than the thermal conductivity of first heat radiation member 22. The thermal conductivity of each of the plurality of first heat transfer members 23 is equal to or higher than 10.0 W/(m·K), preferably equal to or higher than 100.0 W/(m·K), and more preferably equal to or higher than 1000.0 W/(m·K). Each of the plurality of first heat transfer members 23 includes a first portion 23A disposed inside first heat radiation member 22 and a second portion 23B connected to first portion 23A and disposed outside first heat radiation member 22. Each of the plurality of first heat transfer members 23 is configured to transfer heat from first portion 23A to second portion 23B. At least a part of first portion 23A of each of the plurality of first heat transfer members 23 extends parallel to third surface 22A. At least a part of first portion 23A of each of the plurality of first heat transfer members 23 is spaced apart from each other in second direction DR2. At least a part of first portion 23A of each of the plurality of first heat transfer members 23 extends parallel to each other along first direction DR1, for example. At least a part of second portion 23B of each of the plurality of first heat transfer members 23 extends parallel to each other along third direction DR3, for example. Each of the plurality of first heat transfer members 23 has, for example, a bent portion between first portion 23A and second portion 23B.

Each of the plurality of first heat transfer members 23 is, for example, a heat pipe. Since the refrigerant vaporizes in first portion 23A of the heat pipe by absorbing heat from first heat radiation member 22, and liquefies in second portion 23B thereof by radiating heat to the outside of first heat radiation member 22, the refrigerant circulates in the heat pipe by capillary action. Second portion 23B of each of the plurality of first heat transfer members 23 is thermally connected to cooler 30.

The cross-sectional shape orthogonal to the extending direction of each of the plurality of first heat transfer members 23 is, for example, a circular shape. The cross-sectional shape orthogonal to the extending direction of each of the plurality of first heat transfer members 23 may be any shape, and may be, for example, an elliptical shape or a rectangular shape.

Each of the plurality of first heat transfer members 23 is configured to transfer heat from first heat radiation member 22 to the outside of first heat radiation member 22. Each of the plurality of first heat transfer members 23 may be configured to form a flow path through which cooling water flows, or may include a graphite sheet made of graphite having a layered crystal structure.

The plurality of first heat transfer members 23 include a first first heat transfer member 231 (hereinafter simply referred to as first heat transfer member 231), a second first heat transfer member 232 (hereinafter simply referred to as first heat transfer member 232), and a third first heat transfer member 233 (hereinafter simply referred to as first heat transfer member 233).

A first portion 231A of first heat transfer member 231 extends along side surface 221A of groove 221. At least a part of first portion 231A of first heat transfer member 231 is disposed to overlap with side surface 221A and transformers 11a and 11b in a direction (for example, second direction DR2) orthogonal to side surface 221A. At least a part of first portion 231A of first heat transfer member 231 is disposed to overlap with each of third surface 22A, substrate 21, and switching elements 10a, 10b, 10c and 10d in third direction DR3. Further, at least a part of first portion 231A of first heat transfer member 231 is disposed to overlap with a part of first wiring pattern 15 disposed between switching element 10a and switching element 10b in third direction DR3 and a part of first wiring pattern 15 disposed between switching element 10c and switching element 10d in first direction DR1.

Preferably, the center of first portion 231A of first heat transfer member 231 is disposed to overlap with side surface 221A and transformers 11a and 11b in a direction orthogonal to side surface 221A, and is disposed to overlap with each of third surface 22A, substrate 21, and switching elements 10a, 10b, 10c and 10d in third direction DR3. More preferably, the entire first portion 231A of first heat transfer member 231 is disposed to overlap with side surface 221A and transformers 11a and 11b in a direction orthogonal to side surface 221A, and is disposed to overlap with each of third surface 22A, substrate 21, and switching elements 10a, 10b, 10c and 10d in third direction DR3.

A first portion 232A of first heat transfer member 232 extends along side surface 221A of groove 221. At least a part of first portion 232A of first heat transfer member 232 is disposed to overlap with side surface 221A and transformers 11a and 11b in a direction (for example, second direction DR2) orthogonal to side surface 221A. At least a part of first portion 232A of first heat transfer member 232 is disposed to overlap with each of rectifier elements 12a, 12b, 12c and 12d in third direction DR3. Further, at least a part of first portion 232A of first heat transfer member 232 is disposed to overlap in third direction DR3 with a part of second wiring pattern 16 disposed between rectifier element 12a and rectifier element 12b in first direction DR1 and a part of second wiring pattern 16 disposed between rectifier element 12c and rectifier element 12d in first direction DR1. First heat transfer member 231 and first heat transfer member 232 are disposed to sandwich groove 221 and transformers 11a and 11b in third direction DR3.

Preferably, the center of first portion 232A of first heat transfer member 232 is disposed to overlap with side surface 221A and transformers 11a and 11b in a direction orthogonal to side surface 221A, and is disposed to overlap with each of third surface 22A, substrate 21, and rectifier elements 12a, 12b, 12c and 12d in third direction DR3. More preferably, the entire first portion 232A of first heat transfer member 232 is disposed to overlap with side surface 221A and transformers 11a and 11b in a direction orthogonal to side surface 221A, and is disposed to overlap with each of third surface 22A, substrate 21, and rectifier elements 12a, 12b, 12c and 12d in third direction DR3.

A first portion 233A of first heat transfer member 233 extends along bottom surface 221B of groove 221. At least a part of first portion 232A of first heat transfer member 232 is disposed to overlap with each of bottom surface 221B, transformer 11a, and transformer 11b in a direction (for example, third direction DR3) orthogonal to bottom surface 221B.

Preferably, the center of first portion 233A of first heat transfer member 233 is disposed to overlap with each of bottom surface 221B, transformer 11a, and transformer 11b in a direction orthogonal to bottom surface 221B. More preferably, the entire first portion 233A of first heat transfer member 233 is disposed to overlap with each of bottom surface 221B, transformer 11a, and transformer 11b in a direction orthogonal to bottom surface 221B.

Each of first portion 231A of first heat transfer member 231, first portion 232A of first heat transfer member 232 and first portion 233A of first heat transfer member 233 is thermally connected to transformers 11a and 11b via first heat radiation member 22 and the heat conductive member 24. Each of first portion 231A of first heat transfer member 231, first portion 232A of first heat transfer member 232, and first portion 233A of first heat transfer member 233 is thermally connected to transformers 11a and 11b without substrate 21 interposed therebetween.

First portion 232A of first heat transfer member 232 is thermally connected to each of switching elements 10a, 10b, 10c and 10d via first heat radiation member 22, substrate 21 and thermally conductive member 24. First portion 233A of first heat transfer member 233 is thermally connected to each of rectifier elements 12a to 12d via first heat radiation member 22 and thermally conductive member 24.

Thermally conductive member 24 has high thermal conductivity and electrical insulation. The thermal conductivity of thermally conductive member 24 is preferably 0.1 W/(m·K) or more, more preferably 1.0 W/(m·K) or more, and still more preferably 10.0 W/(m·K) or more. Thermally conductive member 24 includes, for example, at least one selected from the group consisting of a thermally conductive grease, a thermally conductive sheet, a thermally conductive adhesive agent, and a thermally conductive gap filler. The gap filler may be, for example, a one-component non-mixed gap filler or a two-component mixed gap filler.

The plurality of positioning members 25 determine the position of substrate 21 and first heat radiation member 22 which are stacked with thermally conductive member 24 interposed therebetween. The plurality of positioning members 25 include, for example, a spacer that extends between substrate 21 and first heat radiation member 22, and a fixing member such as a screw that fixes each of substrate 21 and first heat radiation member 22 to the spacer. By the plurality of positioning members 25, the dimension (thickness) of thermally conductive member 24 in third direction DR3 is held constant regardless of its position in first direction DR1 and second direction DR2. As a result, since a local region with low insulation (low withstand voltage) and low heat radiation is not formed in thermally conductive member 24, the reliability of the power conversion device can be prevented from decreasing. For example, when the thickness of thermally conductive member 24 is not uniform, since the heat radiation of a thick-wall region where the thickness of thermally conductive member 24 is locally thick is lower than that of a thin-wall region where the thickness of thermally conductive member 24 is thinner, hot spots are likely to be formed in the thick-wall region. Therefore, cracks may occur in a soldered portion of substrate 21 located in the thick-wall region of thermally conductive member 24. In the power conversion device according to the present embodiment, since the thickness of thermally conductive member 24 is uniform, cracks are less likely to be formed.

The plurality of positioning members 25 include, for example, a first positioning member 25 extending between third surface 22A of first heat radiation member 22 and substrate 21, and a second positioning member 25 extending between the bottom surface of groove 221 of first heat radiation member 22 and substrate 21. The material of each of the plurality of positioning members 25 is not particularly limited, and may include at least one of a metal and a resin.

Cooler 30 is configured to cool second portion 23B of each of the plurality of first heat transfer members 23. Cooler 30 may have any structure capable of cooling second portion 23B of each of the plurality of first heat transfer members 23. Cooler 30 includes, for example, at least one cooling body 31 which is thermally connected to second portions 231B, 232B and 233B of the plurality of first heat transfer members 231, 232 and 233 (see FIG. 5), and at least one fan 32 that blows air to the at least one cooling body 31. Cooling body 31 is forcibly air-cooled by fan 32. The blowing direction of fan 32 is, for example, the same as second direction DR2. Cooling body 31 may include a wind tunnel and fins disposed on an inner surface of the wind tunnel.

Cooler 30 is arranged side by side with substrate 21 and first heat radiation member 22 in first direction DR1. One of transformers 11a and 11b is farther away from cooler 30 than the other transformer. For example, transformer 11b is farther away from cooler 30 than transformer 11a. Switching elements 10a, 10b, 10c and 10d are arranged side by side in first direction DR1, starting from the side of cooler 30.

Rectifier elements 12a, 12b, 12c and 12d are arranged side by side in first direction DR1, starting from the side of cooler 30.

The structure of each of transformers 11a and 11b is not particularly limited.

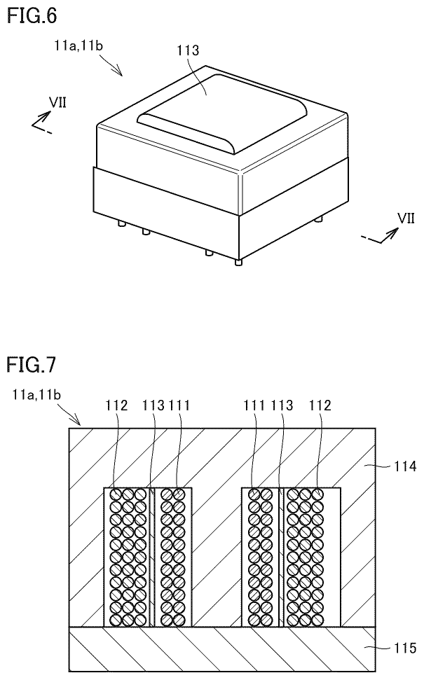

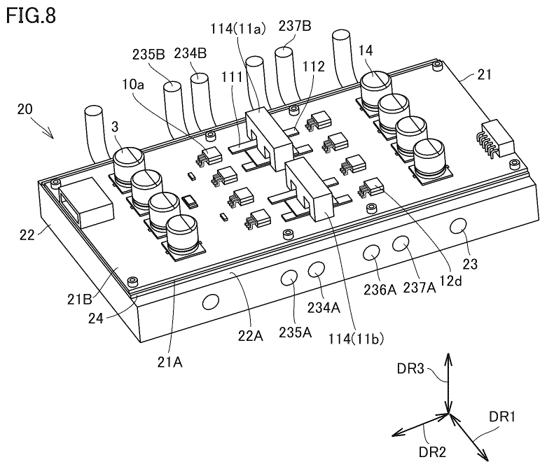

As illustrated in FIGS. 6 and 7, each of transformers 11a and 11b has, for example, a core (EI core) having a structure in which an E-type core 114 and an I-type core 115 are combined. Each of transformers 11a and 11b may have a structure in which two U-shaped cores are combined, a structure in which two E-shaped cores are combined, or a structure in which a T-shaped core and a U-shaped core are combined.

In each of transformers 11a and 11b, secondary winding 112 is wound on primary winding 111 so as to surround primary winding 111, for example. In this case, each of transformers 11a and 11b may further include a U-shaped spacer 113 inserted between primary winding 111 and secondary winding 112. Spacer 113 in each of transformers 11a and 11b is exposed from a surface opposite to the other surface where terminals are electrically connected to substrate 21, for example. In the power conversion device according to the first embodiment, the surface where spacer 113 is exposed may be thermally connected to bottom surface 221B of groove 221 via thermally conductive member 24.

The core of each of transformers 11a and 11b is, for example, a ferrite core such as a manganese zinc (Mn—Zn) ferrite core or a nickel zinc (Ni—Zn) ferrite core, an amorphous core, or an iron powder core.

Power unit 20 may further include a first heat transfer member which has a first portion thermally connected to input capacitor 3 and a first heat transfer member which has a first portion thermally connected to smoothing capacitor 14.

### Effects of Power Conversion Device

The power conversion device according to the first embodiment includes first heat transfer member 231 which includes first portion 231A thermally connected to each of transformers 11a and 11b (first electronic components) via first heat radiation member 22. Therefore, the heat generated in each of transformers 11a and 11b can be rapidly transferred to second portion 231B of first heat transfer member 231 through first heat radiation member 22 and first portion 231A of first heat transfer member 231, and can be released from the second portion 231B to the outside of the power conversion device by cooler 30 or the like. Therefore, in the power conversion device, it is not necessary to arrange a plurality of electronic components that generate a large amount of heat, such as transformers 11a and 11b, side by side in second direction DR2 along the end side of substrate 21 which is closer to cooler 30. In addition, even when one electronic component that generates a large amount of heat (for example, a relatively large package that includes a large number of electronic components) is mounted on substrate 21, it is not necessary to arrange the electronic component so that the longitudinal direction of the electronic component is the same as the direction of the end side of substrate 21 which is closer to cooler 30. Therefore, according to the power conversion device of the first embodiment, it is possible to make the power conversion device smaller in size and higher in output as compared with the conventional power conversion device mentioned above.

Specifically, in the power conversion device according to the first embodiment, transformers 11a and 11b are arranged side by side in first direction DR1. At least a part of first portion 231A of first heat transfer member 231 is disposed to extend in first direction DR1 and overlap with each of first heat radiation member 22 and transformers 11a and 11b in third direction DR3 orthogonal to the first surface. In the power conversion device with the above-described configuration, the heat radiation of each of transformers 11a and 11b is improved as compared with the power conversion device without the above-described configuration.

In addition, in the conventional power conversion device mentioned above, since the arrangement of the electronic components that generate a large amount of heat is limited, the wiring path of a circuit that includes the electronic components becomes longer and the parasitic inductance becomes greater, which may cause a high switching surge to occur. As a result, a semiconductor element having a high breakdown voltage and a countermeasure against noise are required in the conventional power conversion device mentioned above, which makes it difficult to reduce the size and the manufacturing cost of the conventional power conversion device. On the other hand, in the power conversion device according to the first embodiment, the arrangement of the electronic components that generate a large amount of heat is not limited by the distance to cooler 30. Therefore, transformers 11a and 11b, switching elements 10a, 10b, 10c and 10d, and rectifier elements 12a, 12b, 12c and 12d may be arranged as illustrated in FIG. 3. Accordingly, in the power conversion device according to the first embodiment, it is possible to suppress the increase of parasitic inductance and the generation of noise, which makes it possible to reduce the size and the manufacturing cost of the power conversion device.

In addition, in the power conversion device according to the first embodiment, since power unit 20 and cooler 30 are arranged side by side in first direction DR1, it is possible to reduce the size of the power conversion device in third direction DR3 (low profile). In addition, since cooling body 31 and fan 32 of cooler 30 are arranged side by side in second direction DR2, it is possible to reduce the size of cooler 30 in third direction DR3 as compared with the case where cooling body 31 and fan 32 are arranged side by side in third direction DR3, and as a result, it is possible to reduce the size of the power conversion device in third direction DR3.

Further, in the power conversion device according to the first embodiment, third surface 22A of first heat radiation member 22 is formed with a groove 221, and the pair of side surfaces 221A of groove 221 are thermally connected to the side surfaces of transformers 11a and 11b. At least a part of first portion 231A of first heat transfer member 231 is disposed to extend along side surface 221A and overlap with each of transformers 11a and 11b and side surface 221A in a direction orthogonal to side surface 221A. Therefore, the heat generated in transformers 11a and 11b can be quickly transferred to first portion 231A of first heat transfer member 231 through the side surfaces of transformers 11a and 11b and side surfaces 221A of groove 221 of first heat radiation member 22.

Furthermore, in the power conversion device according to the first embodiment, at least a part of first portion 231A of first heat transfer member 231 is disposed to overlap with each of switching elements 10a, 10b, 10c and 10d (second electronic components) in third direction DR3, and is thermally connected to each of switching elements 10a, 10b, 10c and 10d via first heat radiation member 22 and substrate 21.

In the power conversion device with the above-mentioned configuration, the heat radiation of each of transformers 11a and 11b and switching elements 10a, 10b, 10c and 10d is improved as compared with the power conversion device without the above-mentioned configuration. In addition, the power conversion device with the above-mentioned configuration can be made smaller in size as compared with a power conversion device when the first heat transfer member in which at least a part of the first portion overlaps with each of switching elements 10a, 10b, 10c and 10d in third direction DR3 is provided as a member separate from the first heat transfer member in which at least a part of the first portion overlaps each of transformers 11a and 11b.

Similarly, in the power conversion device according to the first embodiment, at least a part of first portion 232A of first heat transfer member 232 is disposed to overlap with side surface 221A and each of transformers 11a and 11b in a direction orthogonal to side surface 221A, and to overlap with each of rectifier elements 12a, 12b, 12c and 12d in third direction DR3. First portion 232A of first heat transfer member 232 is thermally connected to each of transformers 11a and 11b via first heat radiation member 22, and is thermally connected to each of rectifier elements 12a, 12b, 12c and 12d via first heat radiation member 22 and substrate 21. In the power conversion device with the above-mentioned configuration, the heat radiation of each of transformers 11a and 11b and rectifier elements 12a, 12b, 12c and 12d is improved as compared with the power conversion device without the above-mentioned configuration. In addition, the power conversion device with the above-mentioned configuration can be made smaller in size as compared with a power conversion device when the first heat transfer member in which at least a part of the first portion overlaps with each of rectifier elements 12a, 12b, 12c and 12d in third direction DR3 is provided as a member separate from the first heat transfer member in which at least a part of the first portion overlaps with each of transformers 11a and 11b.

Further, in the power conversion device according to the first embodiment, bottom surface 221B of groove 221 is thermally connected to transformer 11a and transformer 11b. At least a part of first portion 233A of first heat transfer member 233 is disposed to extend along bottom surface 221B and overlap with each of transformers 11a and 11b and bottom surface 221B in a direction orthogonal to bottom surface 221B. In the power conversion device with the above-mentioned configuration, the heat radiation of each of transformers 11a and 11b is improved as compared with the power conversion device without first heat transfer member 233.

Further, in the power conversion device according to the first embodiment, at least a part of first portion 231A of first heat transfer member 231 is disposed to overlap with a part of first wiring pattern 15 for electrically connecting inverter circuit 4 and primary winding 111 of transformers 11a and 11b in third direction DR3.

Similarly, at least a part of first portion 232A of first heat transfer member 232 is disposed to overlap with a part of second wiring pattern 16 for electrically connecting rectifier circuit 6 and secondary winding 112 of transformers 11a and 11b in third direction DR3. Therefore, the Joule heat generated in first wiring pattern 15 and second wiring pattern 16 can also be quickly transferred to first portion 231A or 232A of first heat transfer member 231 or 232 through first heat radiation member 22. In other words, in the power conversion device according to the first embodiment, the heat radiation of first wiring pattern 15 and second wiring pattern 16 is improved equal to the heat radiation of the transformers 11a and 11b, and the like.

### Modification

The power conversion device illustrated in FIGS. 2 to 5 includes a plurality of first heat transfer members thermally connected to each of switching elements 10a, 10b, 10c and 10d, rectifier elements 12a to 12d, and transformers 11a and 11b, but is not limited thereto. The power conversion device according to the embodiment of the present disclosure may include at least one first heat transfer member thermally connected to at least one electronic component that generates a relatively large amount of heat. From a different viewpoint, in the power conversion device according to the embodiment of the present disclosure, the first electronic component thermally connected to the first portion of the at least one first heat transfer member may be at least one of transformers 11a and 11b, switching elements 10a, 10b, 10c and 10d, rectifier elements 12a to 12d, and smoothing reactor 13.

In the power conversion device according to the first embodiment, the arrangement of the electronic components and the arrangement of the at least one first heat transfer member 23 are not particularly limited as long as the at least one first heat transfer member is thermally connected to the at least one electronic component that generates a large amount of heat. At least one first heat transfer member 23 may be thermally connected to various types of electronic components. In addition, each of the plurality of electronic components of the same type may be thermally connected to different first heat transfer members. For example, one first heat transfer member 23 may be thermally connected to transformer 11a and switching element 10a, and the other first heat transfer member 23 may be thermally connected to transformer 11b and switching element 10b.

The at least one first heat transfer member may be thermally connected to an electronic component that generates a relatively small amount of heat. For example, first heat transfer member 231 may be thermally connected to input capacitor 3 in addition to switching elements 10a, 10b, 10c and 10d, transformers 11a and 11b, and first wiring pattern 15. Preferably, the electronic component that generates a relatively large amount of heat is thermally connected to a region closer to the second portion of the first portion of the first heat transfer member than the electronic component that generates a relatively small amount of heat.

In the power conversion device illustrated in FIGS. 2 to 5, first portion 231A of first heat transfer member 231 linearly extends in first direction DR1, but is not limited thereto. First portion 231A may have, for example, a bent shape, for example, a U-shape, an L-shape, or a serpentine shape.

In the power conversion device illustrated in FIGS. 2 to 5, transformer circuit 5 of power supply circuit 1 includes two transformers 11a and 11b, but the number of transformers included in transformer circuit 5 is not limited to two. The number of transformers included in transformer circuit 5 may be one. When the one transformer has a longitudinal direction and a lateral direction as viewed from third direction DR3, the longitudinal direction of one transformer is disposed in first direction DR1, and the lateral direction of the transformer is disposed along second direction DR2. Thus, it is possible to make the power conversion device smaller in size and higher in output as compared with the conventional power conversion device described above.

Groove 221 may be configured to accommodate at least a part of each of transformers 11a and 11b. Groove 221 may be formed on at least a partial region between one end surface and the other end surface of first heat radiation member 22 in first direction DR1.

### Second Embodiment

As illustrated in FIGS. 8 to 10, the power conversion device according to a second embodiment has the same configuration and effects as the power conversion device according to the first embodiment described above, unless otherwise specified. Therefore, the same components as those of the first embodiment are denoted by the same reference numerals, and the description thereof will not be repeated.

As illustrated in FIGS. 8 to 10, in power unit 20 of the power conversion device according to the second embodiment, at least a part of transformer 11a or 11b is disposed on second surface 21B together with switching elements 10a, 10b, 10c and 10d and rectifier elements 12a, 12b, 12c and 12d.

Each of transformers 11a and 11b includes a portion disposed on first surface 21A, a portion disposed on second surface 21B, and a portion inserted into a through hole penetrating first surface 21A and second surface 21B.

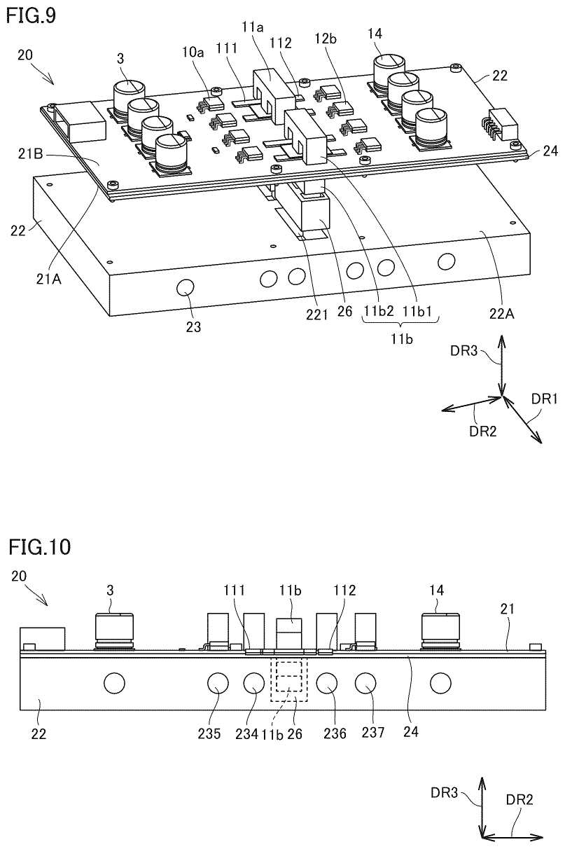

Each of transformers 11a and 11b has, for example, a structure in which an E-type core and an I-type core are combined. In this case, for example, a part of the E-shaped core is disposed on first surface 21A, and the I-shaped core is disposed on second surface 21B. Each leg of the E-shaped core is inserted into a through hole of substrate 21 formed so as to penetrate first surface 21A and second surface 21B. As illustrated in FIG. 9, transformer 11b includes a portion 11b1 disposed on first surface 21A and a portion 11b2 disposed on second surface 21B. Primary winding 111 and secondary winding 112 of each of transformers 11a and 11b are formed as a wiring pattern on, for example, second surface 21B of substrate 21.

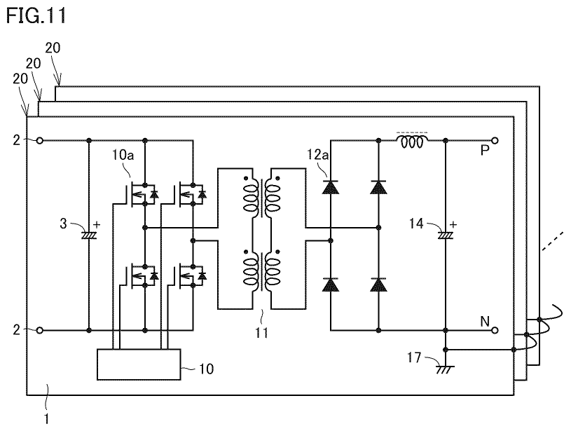

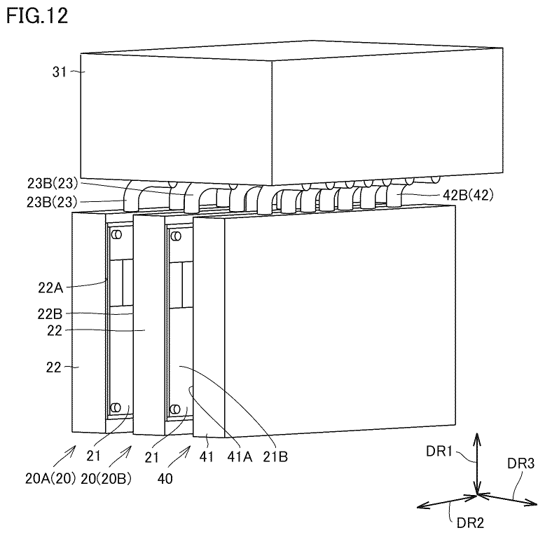

As illustrated in FIGS. 9 and 10, third surface 22A of first heat radiation member 22 is formed with a groove 221 for accommodating a part of each of transformers 11a and 11b disposed on first surface 21A. Groove 221 is formed, for example, only on a partial region between one end surface and the other end surface in first direction DR1 of first heat radiation member 22. Note that groove 221 may be formed so as to extend from one end surface to the other end surface in first direction DR1 of first heat radiation member 22.

The part of each of transformers 11a and 11b disposed on first surface 21A as described above is thermally connected to the inner peripheral surface of groove 221 via a thermally conductive member 26. Thermally conductive member 26 is formed as a different member of thermally conductive member 24, for example. Thermally conductive member 26 may be integrally formed as the same member as thermally conductive member 24.

Thermally conductive member 26 has high thermal conductivity and electrical insulation. The thermal conductivity of thermally conductive member 26 is preferably 0.1 W/(m·K) or more, more preferably 1.0 W/(m·K) or more, and still more preferably 10.0 W/(m·K) or more. Thermally conductive member 26 includes, for example, at least one selected from the group consisting of a thermally conductive grease, a thermally conductive sheet, a thermally conductive adhesive agent, and a thermally conductive gap filler. The gap filler may be, for example, a one-component non-mixed gap filler or a two-component mixed gap filler. In the case where thermally conductive member 26 is a thermally conductive gap filler, after the thermally conductive gap filler is filled in groove 221, the part of each of transformers 11a and 11b (which are mounted on substrate 21) disposed on first surface 21A is accommodated inside groove 221. Thereafter, the thermally conductive gap filler is cured, whereby transformers 11a and 11b are bonded to first heat radiation member 22 by thermally conductive member 26, in other words, transformers 11a and 11b are thermally connected to first heat radiation member 22 via thermally conductive member 26.

Power unit 20 includes a plurality of first heat transfer members 23. The plurality of first heat transfer members 23 include a fourth first heat transfer member 234 (hereinafter also simply referred to as first heat transfer member 234), a fifth first heat transfer member 235 (hereinafter also simply referred to as first heat transfer member 235), a sixth first heat transfer member 236 (hereinafter also simply referred to as first heat transfer member 236), and a sixth first heat transfer member 237 (hereinafter also simply referred to as first heat transfer member 237).

A first portion 234A of first heat transfer member 234 extends along a side surface of groove 221. At least a part of first portion 234A of first heat transfer member 234 is disposed to overlap with the side surface and transformers 11a and 11b in a direction (for example, second direction DR2) orthogonal to the side surface. At least a part of first portion 234A of first heat transfer member 234 is disposed to overlap with each of third surface 22A, substrate 21, and primary winding 111 in third direction DR3.

Preferably, the center of first portion 234A of first heat transfer member 234 is disposed to overlap with the side surface and transformers 11a and 11b in a direction orthogonal to the side surface, and is disposed to overlap with each of third surface 22A, substrate 21 and primary winding 111 in third direction DR3. More preferably, the entire first portion 234A of first heat transfer member 234 is disposed to overlap with the side surface and transformers 11a and 11b in a direction orthogonal to the side surface, and is disposed to overlap with each of third surface 22A, substrate 21 and primary winding 111 in third direction DR3.

At least a part of a first portion 235A of first heat transfer member 235 is disposed to overlap with each of third surface 22A, substrate 21, and switching elements 10a, 10b, 10c and 10d in third direction DR3.

Preferably, the center of first portion 235A of first heat transfer member 235 is disposed to overlap with each of third surface 22A, substrate 21, and switching elements 10a, 10b, 10c and 10d in third direction DR3. More preferably, the entire first portion 235A of first heat transfer member 235 is disposed to overlap with each of third surface 22A, substrate 21, and switching elements 10a, 10b, 10c and 10d in third direction DR3.

Each of first heat transfer member 236 and first heat transfer member 237 is, for example, symmetrical with each of first heat transfer member 234 and first heat transfer member 235 with respect to groove 221.

A first portion 236A of first heat transfer member 236 extends along a side surface of groove 221. At least a part of first portion 236A of first heat transfer member 236 is disposed to overlap with the side surface and transformers 11a and 11b in a direction (for example, second direction DR2) orthogonal to the side surface. At least a part of first portion 236A of first heat transfer member 236 is disposed to overlap with each of third surface 22A, substrate 21 and secondary winding 112 in third direction DR3.

Preferably, the center of first portion 236A of first heat transfer member 236 is disposed to overlap with the side surface and transformers 11a and 11b in a direction orthogonal to the side surface, and is disposed to overlap with each of third surface 22A, substrate 21 and secondary winding 112 in third direction DR3. More preferably, the entire first portion 236A of first heat transfer member 236 is disposed to overlap with the side surface and transformers 11a and 11b in a direction orthogonal to the side surface, and is disposed to overlap with each of third surface 22A, substrate 21, and secondary winding 112 in third direction DR3.

At least a part of a first portion 237A of first heat transfer member 237 is disposed to overlap with each of third surface 22A, substrate 21, and rectifier elements 12a, 12b, 12c and 12d in third direction DR3.

Preferably, the center of first portion 237A of first heat transfer member 237 is disposed to overlap with each of third surface 22A, substrate 21, and rectifier elements 12a, 12b, 12c and 12d in third direction DR3. More preferably, the entire first portion 237A of first heat transfer member 237 is disposed to overlap with each of third surface 22A, substrate 21, and rectifier elements 12a, 12b, 12c and 12d in third direction DR3.

Also in the power conversion device according to the second embodiment, the same effects as those of the power conversion device according to the first embodiment may be achieved.

In the power conversion device according to the second embodiment, heat generated in primary winding 111 and secondary winding 112 of transformers 11a and 11b is quickly transferred to the first portions 234A and 236A of the first heat transfer members 234 and 236 via first heat radiation member 22, and thus the heat radiation of transformers 11a and 11b is improved.

Furthermore, in the power conversion device according to the second embodiment, each of switching elements 10a, 10b, 10c and 10d is thermally connected to first heat transfer member 235 via first heat radiation member 22, and is thermally connected to first heat transfer member 234 via primary winding 111 and first heat radiation member 22. Similarly, each of rectifier elements 12a, 12b, 12c and 12d is thermally connected to first heat transfer member 237 via first heat radiation member 22, and is thermally connected to first heat transfer member 236 via secondary winding 112 and first heat radiation member 22. Therefore, in the power conversion device according to the second embodiment, the heat radiation of switching elements 10a, 10b, 10c and 10d and rectifier elements 12a, 12b, 12c and 12d is also improved.

### Modification

Transformers 11a and 11b may be entirely disposed on first surface 21A. Third surface 22A of first heat radiation member 22 may not be formed with a groove.

The wiring pattern of substrate 21 may be formed only on second surface 21B. Substrate 21 may be a metal base substrate obtained by stacking a metal base body, an insulating layer, and a wiring layer in this order. In this case, first surface 21A is a surface of the metal base body, and second surface 21B is a surface of the wiring layer. The thermal conductivity of the metal base body is preferably 1.0 W/(m·K) or more, more preferably 10.0 W/(m·K) or more, and still more preferably 100.0 W/(m·K) or more. The metal material of the metal base body is, for example, copper (Cu), iron (Fe), aluminum (Al), or an alloy thereof.

Primary winding 111 and secondary winding 112 of each of transformers 11a and 11b may be a laminate busbar mounted on substrate 21. In this case, primary winding 111 and secondary winding 112 may be formed by laminating a laminated body of an insulating film sheet and a metal conductor. The insulating film sheet includes, for example, at least one selected from the group consisting of a film formed of polyethylene terephthalate (PET), a film formed of polyimide (PI), and a sheet formed of aramid (all aromatic polyamide) fibers. The insulating film sheet may be adhered to the metal conductor by an adhesive layer or a bonding layer.

Similar to power unit 20, power unit 20 may include first heat transfer member 233.

The power conversion device according to the second embodiment may be modified in the same manner as the modification of the power conversion device according to the first embodiment as described above.

### Third Embodiment

The power conversion device according to a third embodiment has the same configuration and effects as the power conversion device according to the first embodiment or the second embodiment described above, unless otherwise specified. Therefore, the same components as those of the first embodiment or the second embodiment are denoted by the same reference numerals, and the description thereof will not be repeated.

As illustrated in FIG. 11, the power conversion device according to the third embodiment includes a plurality of power units 20. Each of the plurality of power units 20 has, for example, the same configuration as power unit 20 according to the second embodiment. Each of the plurality of power units 20 includes a power supply circuit 1. Smoothing circuit 7 of each of the plurality of power supply circuits 1 has a ground terminal 17. First heat radiation member 22 is electrically connected to ground terminal 17. As a result, the potential of one side of the smoothing capacitors 14 of each of the plurality of power units 20 and the potential of first heat radiation member 22 are set to the same potential as the ground.

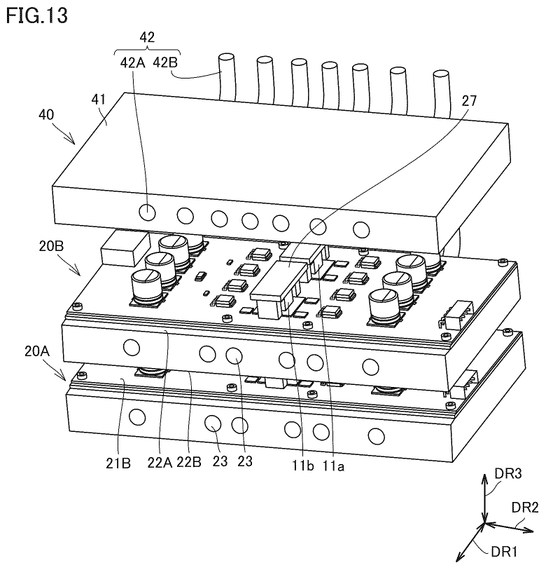

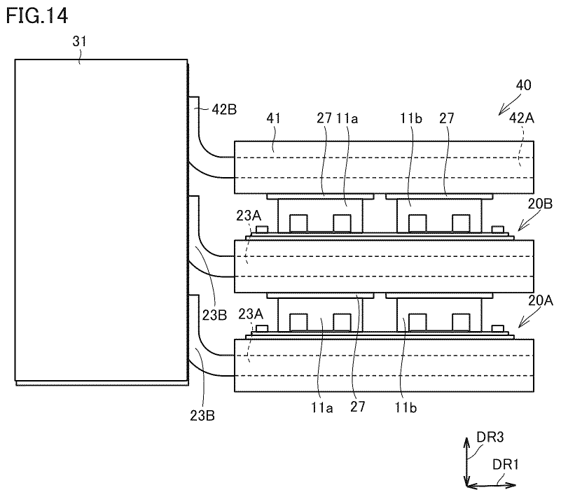

As illustrated in FIGS. 12 to 15, the plurality of power units 20 are stacked in third direction DR3. The plurality of power units 20 include a first power unit 20A and a second power unit 20B. Second surface 21B of substrate 21 of first power unit 20A faces fourth surface 22B of first heat radiation member 22 of second power unit 20B. Fourth surface 22B of first heat radiation member 22 of second power unit 20B is thermally connected to transformers 11a and 11b of first power unit 20A. Fourth surface 22B of first heat radiation member 22 of second power unit 20B is thermally connected to the top surface of transformers 11a and 11b of first power unit 20A via, for example, a thermally conductive member 27.

Thermally conductive member 27 has high thermal conductivity and electrical insulation. The thermal conductivity of thermally conductive member 27 is preferably 0.1 W/(m·K) or more, more preferably 1.0 W/(m·K) or more, and still more preferably 10.0 W/(m·K) or more. Thermally conductive member 27 includes, for example, at least one selected from the group consisting of a thermally conductive grease, a thermally conductive sheet, a thermally conductive adhesive agent, and a thermally conductive gap filler. The gap filler may be, for example, a one-component non-mixed gap filler or a two-component mixed gap filler.

Fourth surface 22B of first heat radiation member 22 of second power unit 20B is spaced apart, for example, from the top surface of each of switching elements 10a, 10b, 10c and 10d and rectifier elements 12a, 12b, 12c and 12d of first power unit 20A. Note that fourth surface 22B of first heat radiation member 22 of second power unit 20B may be thermally connected to the top surface of each of switching elements 10a, 10b, 10c and 10d and rectifier elements 12a, 12b, 12c and 12d of first power unit 20A via a thermally conductive member.

As illustrated in FIGS. 12 to 15, the power conversion device according to the third embodiment further includes a heat radiation unit 40. The plurality of power units 20 and heat radiation units 40 are stacked in third direction DR3 with an interval interposed therebetween. Heat radiation unit 40 is disposed on one side of second power unit 20B opposite to the side where first power unit 20A is disposed.

Heat radiation unit 40 includes a second heat radiation member 41 and a plurality of second heat transfer members 42. Second heat radiation member 41 has, for example, the same configuration as first heat radiation member 22. Second heat transfer member 42 has, for example, the same configuration as first heat transfer member 41. Second heat radiation member 41 is thermally connected to second power unit 20B. Second heat radiation member 41 has a fifth surface 41A facing second surface 21B of substrate 21 of second power unit 20B. Fifth surface 41A of second heat radiation member 41 is thermally connected to transformers 11a and 11b of second power unit 20B. Fifth surface 41A is orthogonal to third direction DR3, for example.

The plurality of second heat transfer members are separate from second heat radiation member 41. The thermal conductivity of each of the plurality of second heat transfer members 42 is higher than the thermal conductivity of second heat radiation member 41. Each of the plurality of second heat transfer members 42 includes a third portion 42A disposed inside second heat radiation member 41 and a fourth portion 42B connected to third portion 42A and disposed outside second heat radiation member 41. Each of the plurality of second heat transfer members 42 is configured to transfer heat from third portion 42A to fourth portion 42B.

At least a part of third portion 42A of each of the plurality of second heat transfer members 42 extends parallel to fifth surface 41A. At least a part of third portion 42A of each of the plurality of second heat transfer members 42 is spaced apart from each other in second direction DR2. At least a part of third portion 42A of each of the plurality of second heat transfer members 42 extends parallel to each other along, for example, first direction DR1. Each of the plurality of second heat transfer members 42 has, for example, the same configuration as each of the plurality of first heat transfer members 23. Each of the plurality of second heat transfer members 42 is, for example, a heat pipe.

Second portion 23B of each of the plurality of first heat transfer members 23 of each of the plurality of power units 20 and fourth portion 42B of each of the plurality of second heat transfer members 42 of heat radiation unit 40 are thermally connected to, for example, one cooling body 31. In other words, the single cooler 30 is configured to cool the plurality of power units 20 and heat radiation unit 40.

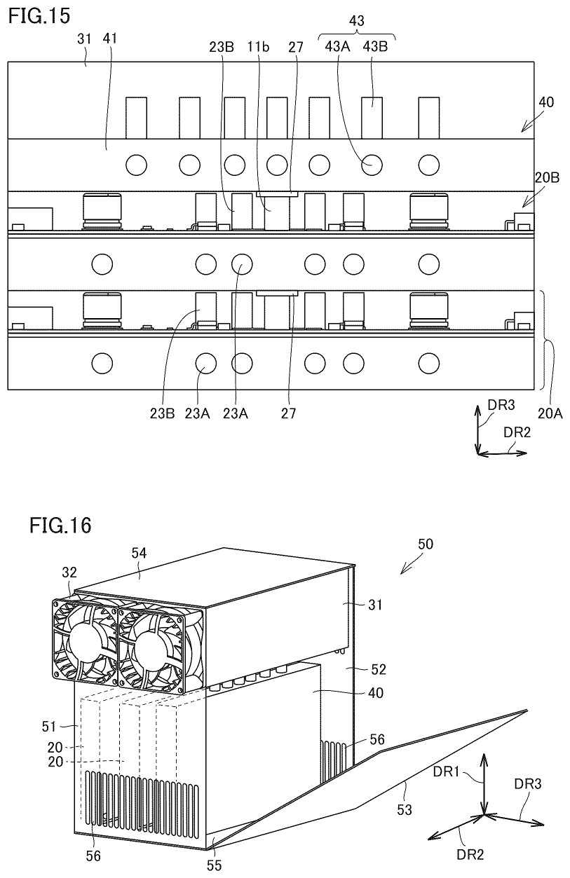

As illustrated in FIG. 16, cooler 30 includes, for example, one cooling body 31 and a plurality of fans 32. The plurality of fans 32 are arranged side by side in third direction DR3, for example. As described above, cooler 30 may include at least one fan 32.

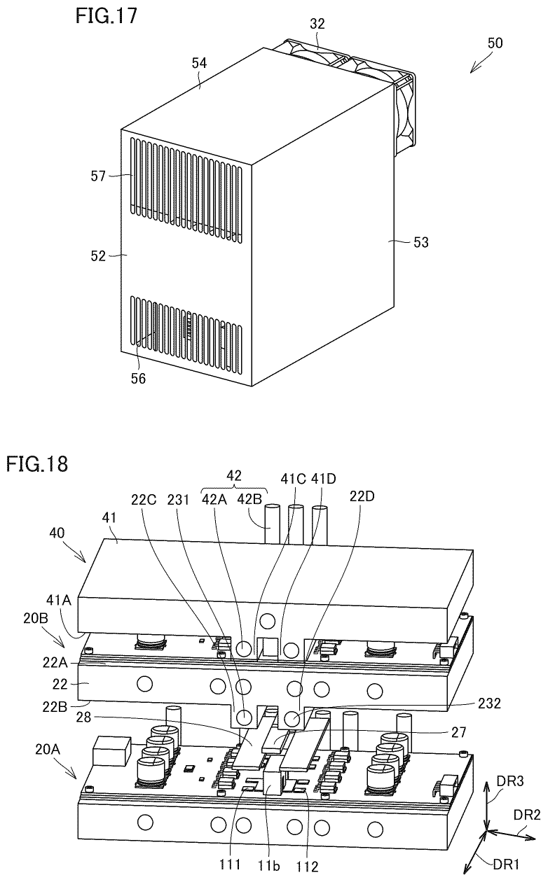

As illustrated in FIGS. 16 and 17, the power conversion device according to the third embodiment further includes a housing 50 that accommodates the plurality of power units 20 and cooling body 31 of cooler 30 therein. Fan 32 of cooler 30 is disposed, for example, outside housing 50. The plurality of power units 20 and cooler 30 are disposed inside housing 50 such that, for example, the vertical direction is identical to first direction DR1. Each of the plurality of power units 20 is spaced apart from each other in third direction DR3. The plurality of power units 20 are disposed, for example, below cooler 30.

Housing 50 includes a plurality of plates that partition the inside and the outside of housing 50. The plurality of plates includes a front plate 51, a rear plate 52, a pair of side plates 53, a top plate 54, and a bottom plate 55. Front plate 51 and rear plate 52 are spaced apart from each other in second direction DR2. The pair of side plates 53 are spaced apart from each other in third direction DR3. Top plate 54 and bottom plate 55 are spaced apart from each other in first direction DR1.

Fan 32 is fixed on front plate 51. Front plate 51 is formed with an opening (not shown) through which air blown from fan 32 to cooling body 31 flows from the outside of housing 50 to the inside thereof. Rear plate 52 is formed with an opening 57 (see FIG. 17) through which the air flowing around cooling body 31 flows out from the inside of housing 50 to the outside thereof. Further, each of front plate 51 and rear plate 52 is formed with a pair of inlet/outlet ports 56 for communicating the inside and the outside of housing 50. A part of each of the plurality of power units 20 is disposed between the pair of inlet/outlet ports 56 in second direction DR2. The pair of inlet/outlet ports 56 is disposed to sandwich a part of each of the plurality of power units 20 in second direction DR2. An air flow path may be formed between the two power units 20 adjacent to each other in third direction DR3, i.e., between the pair of inlet/outlet ports 56. In front plate 51, the pair of inlet/outlet ports 56 is formed below the opening.

The number and shape of the inlet/outlet ports 56 are not particularly limited. A fan may be provided to create an air flow passing through the pair of inlet/outlet ports 56.

Also in the power conversion device according to the third embodiment, the same effects as those of the power conversion device according to the first embodiment may be achieved.

Further, in the power conversion device according to the third embodiment, transformers 11a and 11b of first power unit 20A are thermally connected not only to first heat radiation member 22 and first heat transfer member 23 of first power unit 20A but also to first heat radiation member 22 and first heat transfer member 23 of second power unit 20B. Further, transformers 11a and 11b of second power unit 20B are thermally connected not only to first heat radiation member 22 and first heat transfer member 23 of second power unit 20B but also to second heat radiation member 41 and second heat transfer member 42 of heat radiation unit 40. Therefore, in the power conversion device according to the third embodiment, transformers 11a and 11b included in the plurality of power units 20 are efficiently cooled.

In addition, in the power conversion device according to the third embodiment, since the potential of first heat radiation member 22 of each of the plurality of power units 20 is the same as the potential of the ground, the radiation noise from each power supply circuit 1 can be shielded by each first heat radiation member 22. As a result, in the power conversion device according to the third embodiment, the radiation noise on each of the plurality of power supply circuits 1 is inhibited, and thereby the malfunction is less likely to occur.

Inside housing 50 of the power conversion device according to the third embodiment, a wind tunnel is formed between first power unit 20A and second power unit 20B, and a wind tunnel is formed between second power unit 20B and heat radiation unit 40. The electronic components mounted on second surface 21B of each of first power unit 20A and second power unit 20B each face a wind tunnel. Within each wind tunnel, convection can be promoted by the chimney effect. Therefore, the air flowing into housing 50 from one air inlet/outlet port 56 can be heated by heat exchange with each of the electronic components when passing through each wind tunnel and discharged out of housing 50 from the other air inlet/outlet port 56. As a result, each electronic component can be cooled by air cooling. Such air cooling is particularly effective in radiating heat from those electronic components that are not thermally connected to first heat transfer member 23 and second heat transfer member 42.

### Modification

In the power conversion device according to the third embodiment, the electronic components other than transformers 11a and 11b may be thermally connected to first heat radiation member 22 of the other power unit 20 which is different from power unit 20 on which the electronic components are mounted or second heat radiation member 41 of heat radiation unit 40. For example, at least one of transformers 11a and 11b, switching elements 10a, 10b, 10c and 10d, and rectifier elements 12a, 12b, 12c and 12d may be thermally connected to first heat radiation member 22 of the other power unit 20 or second heat radiation member 41 of heat radiation unit 40.

The power conversion device according to the third embodiment can be modified in the same manner as the modification of the first or second embodiment described above. Heat radiation unit 40 may be provided in the power conversion device according to the first or second embodiment.

### Fourth Embodiment

The power conversion device according to a fourth embodiment has the same configuration and effects as the power conversion device according to the third embodiment described above, unless otherwise specified. Therefore, the same components as those of the third embodiment are denoted by the same reference numerals, and the description thereof will not be repeated.

As illustrated in FIG. 18, in the power conversion device according to the fourth embodiment, first heat radiation member 22 of second power unit 20B includes a first protruding portion 22C and a second protruding portion 22D, each of which protrudes from fourth surface 22B toward second surface 21B of first power unit 20A.

Each of first protruding portion 22C and second protruding portion 22D is disposed to overlap with a part of transformers 11a and 11b of first power unit 20A disposed on second surface 21B in second direction DR2. First protruding portion 22C and second protruding portion 22D are disposed to sandwich a part of transformers 11a and 11b of first power unit 20A disposed on second surface 21B in second direction DR2.

The top surface of each of first protruding portion 22C and second protruding portion 22D is thermally connected to second surface 21B of substrate 21 of first power unit 20A. The top surface of first protruding portion 22C is thermally connected to primary winding 111 (third electronic component) mounted on second surface 21B of substrate 21 of first power unit 20A via, for example, a thermally conductive member 28. The top surface of second protruding portion 22D is thermally connected to secondary winding 112 (third electronic component) mounted on second surface 21B of substrate 21 of first power unit 20A via, for example, thermally conductive member 28.

Thermally conductive member 28 has high thermal conductivity and electrical insulation. The thermal conductivity of thermally conductive member 28 is preferably 0.1 W/(m·K) or more, more preferably 1.0 W/(m·K) or more, and still more preferably 10.0 W/(m·K) or more. Thermally conductive member 28 includes, for example, at least one selected from the group consisting of a thermally conductive grease, a thermally conductive sheet, a thermally conductive adhesive agent, and a thermally conductive gap filler. The gap filler may be, for example, a one-component non-mixed gap filler or a two-component mixed gap filler. Thermally conductive member 28 may have a configuration equivalent to any of the thermally conductive members 24, 26 and 27.

First portion 231A of first heat transfer member 231 is disposed inside first protruding portion 22C. For example, the entire first portion 231A is sandwiched between both side surfaces of first protruding portion 22C. At least a part of first portion 231A of first heat transfer member 231 is disposed to overlap with a part of transformers 11a and 11b of first power unit 20A disposed on second surface 21B in second direction DR2. At least a part of first portion 231A of first heat transfer member 231 is disposed to overlap with primary winding 111 of first power unit 20A in third direction DR3.

First portion 232A of first heat transfer member 232 is disposed inside second protruding portion 22D. For example, the entire first portion 232A is sandwiched between both side surfaces of second protruding portion 22D. At least a part of first portion 231A of first heat transfer member 232 is disposed to overlap with a part of transformers 11a and 11b of first power unit 20A disposed on second surface 21B in second direction DR2. At least a part of first portion 231A of first heat transfer member 232 is disposed to overlap with secondary winding 112 of first power unit 20A in third direction DR3.

As illustrated in FIG. 18, second heat radiation member 41 of heat radiation unit 40 includes a third protruding portion 41C and a fourth protruding portion 41D, each of which protrudes from fifth surface 41A toward second surface 21B of second power unit 20B. Third protruding portion 41C and fourth protruding portion 41D have, for example, the same configuration as first protruding portion 22C and second protruding portion 22D.

The top surface of each of third protruding portion 41C and fourth protruding portion 41D is thermally connected to second surface 21B of substrate 21 of second power unit 20B. The top surface of third protruding portion 41C is thermally connected to primary winding 111 which is provided as a wiring pattern on second surface 21B of substrate 21 of second power unit 20B via, for example, thermally conductive member 28. The top surface of fourth protruding portion 41D is thermally connected to secondary winding 112 which is provided as a wiring pattern on second surface 21B of substrate 21 of second power unit 20B via, for example, thermally conductive member 28.

The plurality of second heat transfer members 42 include a first group of second heat transfer members 421 (hereinafter simply referred to as second heat transfer member 421) and a group of second heat transfer members 422 (hereinafter simply referred to as second heat transfer member 422). Third portion 421A of each of the first group of second heat transfer members 421 is disposed inside third protruding portion 41C or fourth protruding portion 41D. For example, the entire third portion 42A is sandwiched between both side surfaces of third protruding portion 41C or fourth protruding portion 41D. Third portion 422A of second heat transfer member 422 is disposed to overlap with a surface region of fifth surface 41A located between third protruding portion 41C and fourth protruding portion 41D in a direction (for example, third direction DR3) orthogonal to fifth surface 41A.

For example, third portion 421A of second heat transfer member 421 and at least a part of third portion 422A of second heat transfer member 422 are disposed to overlap with transformers 11a and 11b of second power unit 20B in second direction DR2. Third portion 421A of second heat transfer member 421 and at least a part of third portion 422A of second heat transfer member 422 are disposed to overlap with primary winding 111 or secondary winding 112 of second power unit 20B in third direction DR3.

At least a part of third protruding portion 41C is disposed to overlap with first protruding portion 22C in third direction DR3, for example. At least a part of fourth protruding portion 41D is disposed to overlap with second protruding portion 22D in third direction DR3, for example.

Also in the power conversion device according to the fourth embodiment, the same effects as those of the power conversion device according to the third embodiment may be achieved.

Further, in the power conversion device according to the fourth embodiment, the heat generated by primary winding 111 and secondary winding 112 of each power unit 20 can be quickly transferred not only to first heat radiation member 22 and first heat transfer member 23 of power unit 20 on which these elements are mounted, but also to first heat radiation member 22 and first heat transfer member 23 of another power unit 20 adjacent to each other in third direction DR3, or to second heat radiation member 41 and second heat transfer member 42 of heat radiation unit 40. As a result, in the power conversion device according to the fourth embodiment, it is possible to prevent hot air from flowing from transformers 11a and 11b to switching elements 10a, 10b, 10c and 10d and rectifier elements 12a, 12b, 12c and 12d, and prevent hot air from flowing from switching elements 10a, 10b, 10c and 10d and rectifier elements 12a, 12b, 12c and 12d to transformers 11a and 11b.

### Modification

In the power conversion device according to the fourth embodiment, first heat radiation member 22 may include at least one of first protruding portion 22C and second protruding portion 22D. Second heat radiation member 41 may include at least one of third protruding portion 41C and fourth protruding portion 41D.

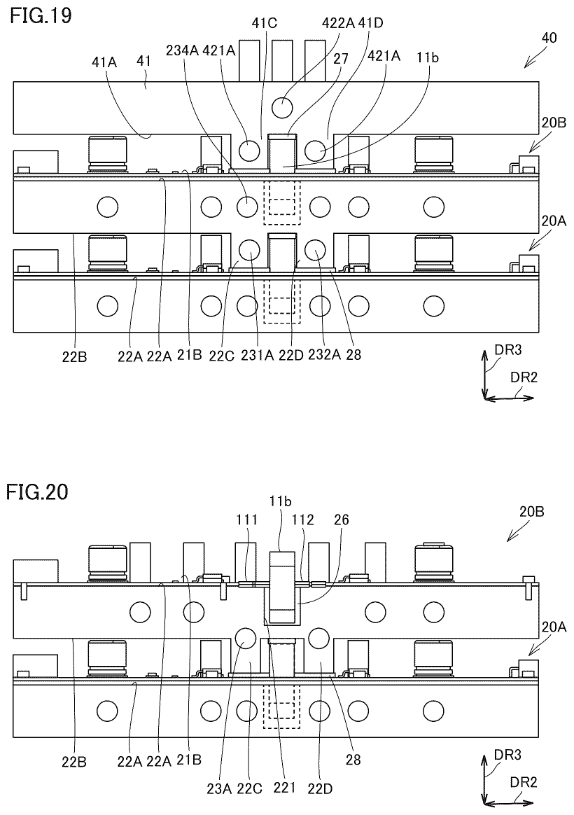

As illustrated in FIG. 20, only a part of first portion 23A of first heat transfer member 23 of second power unit 20B may be disposed inside first protruding portion 22C and second protruding portion 22D. First portion 23A of first heat transfer member 23 of second power unit 20B may include a portion disposed to overlap each of transformers 11a and 11b of second power unit 20B in second direction DR2, and a portion disposed to overlap each of transformers 11a and 11b of first power unit 20A in second direction DR2. First portion 23A of first heat transfer member 23 of second power unit 20B is thermally connected not only to transformers 11a and 11b of second power unit 20B but also to transformers 11a and 11b of first power unit 20A. Power unit 20 in FIG. 20 is suitable when, for example, each of primary winding 111 and secondary winding 112 has an allowable temperature, and thereby the heat radiation required by each of primary winding 111 and secondary winding 112 is lower than the heat radiation realized by the configuration illustrated in FIGS. 18 and 19.

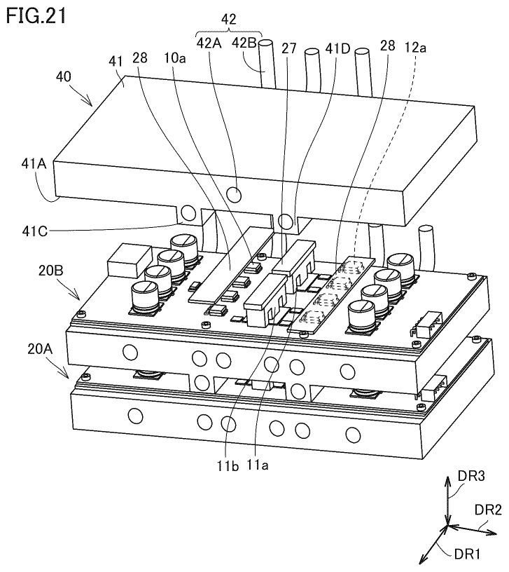

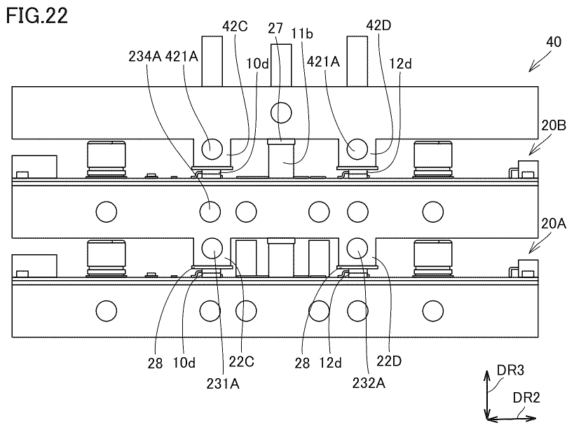

As illustrated in FIGS. 21 and 22, first protruding portion 22C and second protruding portion 22D of second power unit 20B may be thermally connected to each of switching elements 10a, 10b, 10c and 10d and rectifier elements 12a, 12b, 12c and 12d of first power unit 20A instead of primary winding 111 and secondary winding 112 of first power unit 20A. First protruding portion 22C and second protruding portion 22D of second power unit 20B may be thermally connected to the top surface of each of switching elements 10a, 10b, 10c and 10d and rectifier elements 12a, 12b, 12c and 12d of first power unit 20A via, for example, thermally conductive member 28.

Similarly, third protruding portion 41C and fourth protruding portion 41D of heat radiation unit 40 may be thermally connected to each of switching elements 10a, 10b, 10c and 10d and rectifier elements 12a, 12b, 12c and 12d (third electronic component) of second power unit 20B instead of primary winding 111 and secondary winding 112 of second power unit 20B. Third protruding portion 41C and fourth protruding portion 41D of heat radiation unit 40 may be thermally connected to the top surface of each of switching elements 10a, 10b, 10c and 10d and rectifier elements 12a, 12b, 12c and 12d of second power unit 20B via thermally conductive member 28.

Thus, the heat generated by switching elements 10a, 10b, 10c and 10d and rectifier elements 12a, 12b, 12c and 12d of each power unit 20 can be quickly transferred not only to first heat radiation member 22 and first heat transfer member 23 of power unit 20 on which these elements are mounted, but also to first heat radiation member 22 and first heat transfer member 23 of another power unit 20 adjacent to each other in third direction DR3, or to second heat radiation member 41 and the second heat transfer member 42 of heat radiation unit 40. As a result, it is possible to prevent hot air from flowing from switching elements 10a, 10b, 10c and 10d and rectifier elements 12a, 12b, 12c and 12d to transformers 11a and 11b.

In addition, the power conversion device according to the fourth embodiment can be modified in the same manner as the modification of the first, second, or third embodiment described above.

### Modification Common to First to Fourth Embodiments

In each of the first to fourth embodiments, cooler 30 has an air-cooling structure in which cooling body 31 is cooled by air blown from fan 32, but the cooling structure of cooler 30 is not limited thereto. In each of the first embodiment to the fourth embodiment, cooler 30 may have a water-cooling structure that is cooled by a liquid (for example, water) sent from a pump or the like.

In each of the first to fourth embodiments, the electronic components constituting at least a part of power supply circuit 1 are mounted on second surface 21B of substrate 21, but the mounting location of the electronic components is not limited to substrate 21. In each of the first embodiment to the fourth embodiment, some of the electronic components may be mounted on a second substrate connected to substrate 21. For example, input capacitor 3 and output capacitor 14 may be mounted on the second substrate.

The two abovementioned modifications may be implemented simultaneously, or only one of the two abovementioned modifications may be implemented in each of the first to fourth embodiments. The details of the two modifications will be described later according to a fifth embodiment and a sixth embodiment.

### Fifth Embodiment

The power conversion device according to a fifth embodiment has the same configuration and effects as the power conversion device according to the third embodiment or the fourth embodiment described above, unless otherwise specified. Therefore, the same components as those of the third or fourth embodiment are denoted by the same reference numerals, and the description thereof will not be repeated.

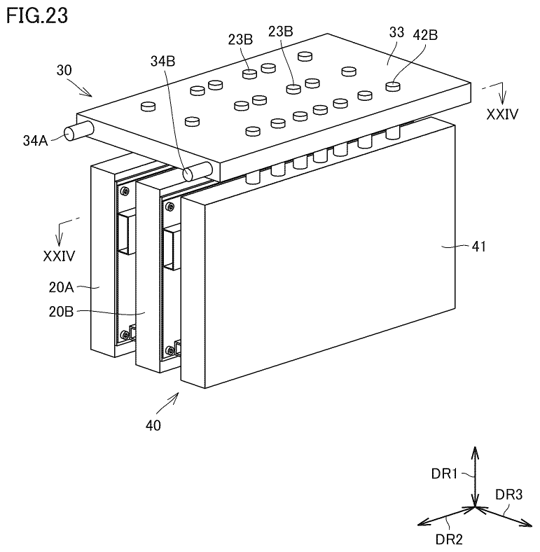

As illustrated in FIG. 23, the power conversion device according to the fifth embodiment includes a cooler 30 having a water-cooling structure. Cooler 30 includes at least one cooling plate 33 (cooling body) and at least one tube 34.

Cooling plate 33 is thermally connected to second portion 23B of each of the plurality of first heat transfer members 23 of each of the plurality of power units 20.

For example, cooling plate 33 is arranged side by side with each of the plurality of power units 20 in first direction DR1. Cooling plate 33 is formed with a through hole or a pothole for accommodating at least a part of second portion 23B. The through hole or the pothole of cooling plate 33 extends, for example, in first direction DR1.

Each second portion 23B includes, for example, a part disposed inside the through hole or the pothole of cooling plate 33. Each second portion 23B extends, for example, in first direction DR1. One end of each second portion 23B is connected to first portion 23A, and the other end thereof opposite to the one end is closed, for example.

The material of cooling plate 33 may be any material having high thermal conductivity, such as aluminum (Al). The thermal conductivity of cooling plate 33 is 0.1 W/(m·K) or more, preferably 1.0 W/(m·K) or more, and more preferably 10.0 W/(m·K) or more.

Tube 34 is thermally connected to cooling plate 33. Tube 34 is thermally connected to second portion 23B of each of the plurality of first heat transfer members 23 via cooling plate 33. Tube 34 is disposed inside cooling plate 33. A flow path for circulating a heat medium is provided inside tube 34. The heat medium is, for example, water. Tube 34 is a pipe, for example. Tube 34 has an inflow port 34A through which the heat medium flows in and an outflow port 34B through which the heat medium flows out. Inflow port 34A and outflow port 34B are arranged side by side on one surface of cooling plate 33, for example.

Inflow port 34A and outflow port 34B are disposed, for example, outside the power conversion device according to the fifth embodiment, and are connected to a heat medium circulation device (not shown) that supplies the heat medium to inflow port 34A and recovers the heat medium from outflow port 34B. In this case, tube 34 constitutes a part of a circulation circuit that circulates the heat medium. The heat medium circulation device is, for example, a chiller capable of cooling the heat medium. The heat medium circulation device is, for example, a chiller capable of cooling the heat medium. Inflow port 34A and outflow port 34B are connected to the heat medium circulation device via, for example, a flexible hose.

Tube 34 is thermally connected to cooling plate 33 via, for example, a thermally conductive member (not shown). The thermally conductive member may have the same configuration as any of the thermally conductive members 24, 26, 27, and 28 described above.

Preferably, in each of the plurality of first heat transfer members 23, first portion 23A and second portion 23B are connected in a straight line. Preferably, each of the plurality of first heat transfer members 23 does not have a bent portion between first portion 23A and second portion 23B.

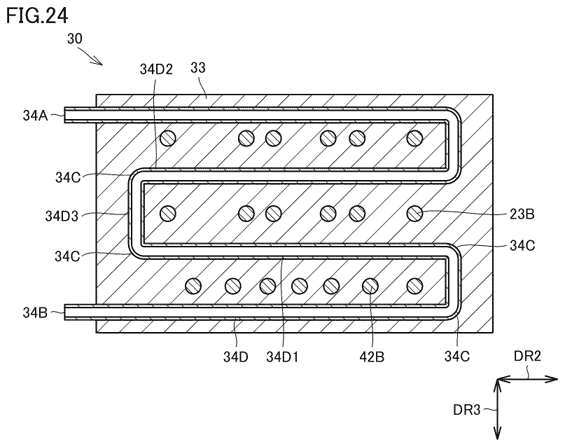

As illustrated in FIG. 24, when viewed from the extending direction of each second portion 23B, tube 34 has, for example, a corrugated shape inside cooling plate 33. The corrugated shape refers to a wavy shape in which a plurality of bent portions are connected in series with each other. Tube 34 includes, for example, a plurality of bent portions 34C and a plurality of straight tube portions 34D inside cooling plate 33. Each of the plurality of bent portions 34C connects the plurality of straight tube portions 34D. Each of the plurality of bent portions 34C has, for example, an L-shape. Each of the plurality of bent portions 34C and each of the plurality of straight tube portions 34D are disposed around second portion 23B inside cooling plate 33.

The plurality of straight tube portions 34D include a first straight tube portion 34D1 and a second straight tube portion 34D2. First straight tube portion 34D1 and second straight tube portion 34D2 are connected to each other in series via at least one bent portion 34C, and are adjacent to each other in third direction DR3. Among the plurality of first heat transfer members 23, the plurality of second portions 23B disposed side by side in second direction DR2 are disposed between first straight tube portion 34D1 and second straight tube portion 34D2.

The plurality of straight tube portions 34D further include, for example, a third straight tube portion 34D3 that connects first straight tube portion 34D1 and second straight tube portion 34D2. First straight tube portion 34D1 and second straight tube portion 34D2 are connected to each other in series via, for example, two bent portions 34C and third straight tube portion 34D3 that connects the two bent portions 34C. Cooling plate 33 is also thermally connected to, for example, fourth portion 42B of each of the plurality of second heat transfer members 42 of heat radiation unit 40. Cooling plate 33 is further formed with a through hole or a pothole for accommodating at least a part of fourth portion 42B. Tube 34 is also thermally connected to fourth portion 42B of each of the plurality of second heat transfer members 42 via cooling plate 33.

The effects of the power conversion device according to the fifth embodiment will be described based on a comparison with a power conversion device according to a comparative example. The power conversion device according to the comparative example does not include a plurality of first heat transfer members 23, and the cooler includes a plurality of pipes thermally connected to the substrate of each of the plurality of power units, a distributor such as a manifold for distributing the heat medium to each of the plurality of pipes, and a flow rate adjustment valve for adjusting the flow rate of the heat medium in each of the plurality of pipes. In such a comparative example, since the structure of the cooler is complicated and the number of components constituting the cooler is large, the size of the power conversion device becomes larger, and the manufacturing cost of the power conversion device becomes higher.

In contrast, in the power conversion device according to the fifth embodiment, since tube 34 through which the heat medium flows is thermally connected to the plurality of first heat transfer members 23 via cooling plate 33, it is not necessary to provide a plurality of tubes and a distributor for distributing the heat medium to each of the plurality of power units 20. Therefore, in the power conversion device according to the fifth embodiment, the structure of cooler 30 can be simplified, and the number of components constituting cooler 30 can be reduced as compared with the comparative example. As a result, the power conversion device according to the fifth embodiment can be made smaller than the comparative example, and the manufacturing cost can be reduced.

In addition, when each of the plurality of first heat transfer members 23 is a heat pipe, the capillary structure provided on the inner wall may collapse at the bent portion of the heat pipe, which lowers the heat transfer capability. In contrast, in the power conversion device according to the fifth embodiment, since each of the plurality of first heat transfer members 23 does not include a bent portion, it is possible to fully utilize the heat transfer capability of the heat pipe.

### Modification

The power conversion device according to the fifth embodiment may include at least one power unit. Cooling plate 33 may be thermally connected to second portion 23B of each of the plurality of first heat transfer members 23 of the at least one power unit 20.

Tube 34 may be provided as a part of a circulation circuit that circulates the heat medium. In this case, cooler 30 may further include a cooling unit capable of cooling the heat medium recovered from tube 34. Tube 34 may include a cavity provided inside cooling plate 33 and a pipe provided outside cooling plate 33.

When viewed from the extending direction of each second portion 23B, tube 34 may not include a bent portion 34C or may include only one bent portion 34C.

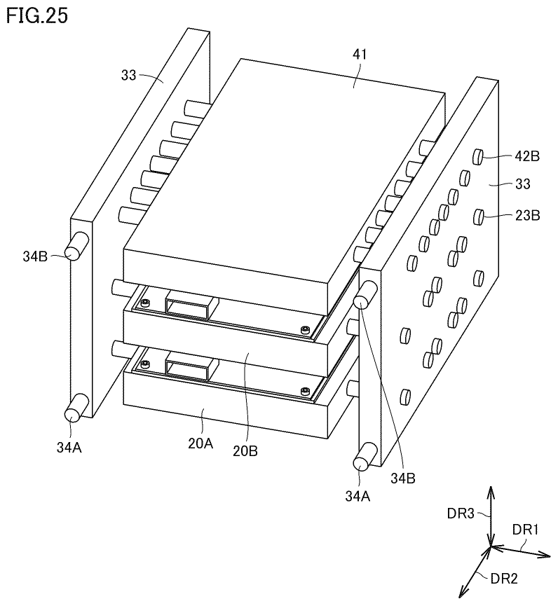

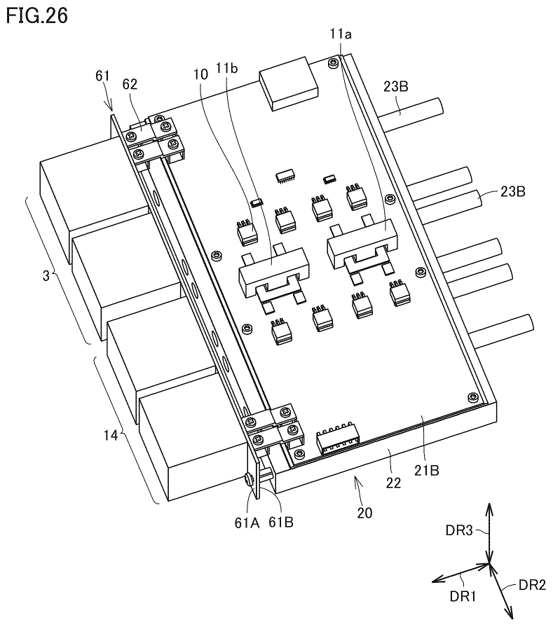

As illustrated in FIG. 25, in the power conversion device according to the fifth embodiment, cooler 30 may include a plurality of cooling plates 33 and 36 and a plurality of pipes 34 and 37 disposed to sandwich the plurality of power units 20.

The plurality of cooling plates 33 and 36 include a first cooling plate 33 and a second cooling plate 36. First cooling plate 33 and second cooling plate 36 are disposed to sandwich the plurality of power units 20 in first direction DR1.

Each of the plurality of first heat transfer members 23 includes a first portion 23A and a pair of second portions 23B connected to one end or the other end of first portion 23A in first direction DR1. One of the pair of second portions 23B is thermally connected to first cooling plate 33. The other one of the pair of second portions 23B is thermally connected to second cooling plate 36.

The plurality of tubes 34 and 37 include a first tube 34 and a second tube 37. First tube 34 is thermally connected to one of the pair of second portions 23B of each of the plurality of first heat transfer members 23 via first cooling plate 33. Second tube 37 is thermally connected to the other one of the pair of second portions 23B of each of the plurality of first heat transfer members 23 via second cooling plate 36.

Preferably, in each of the plurality of first heat transfer members 23, first portion 23A and the pair of second portions 23B are connected in a straight line.

First tube 34 and second tube 37 are independent of each other, for example. First tube 34 and second tube 37 may be connected to each other in parallel or in series.

In the power conversion device in FIG. 25, the heat transferred to each of the plurality of first heat transfer members 23 can be discharged from each of the pair of second portions 231B to the heat medium flowing through first tube 34 or second tube 37. Therefore, the heat radiation of the power conversion device illustrated in FIG. 25 is higher than that of the power conversion device illustrated in FIG. 23.

### Sixth Embodiment

The power conversion device according to a sixth embodiment has the same configuration and effects as the power conversion device according to the third and fourth embodiments described above, unless otherwise specified. Therefore, the same components as those of the third and fourth embodiments are denoted by the same reference numerals, and the description thereof will not be repeated.

As illustrated in FIG. 26, the power conversion device according to the sixth embodiment further includes a second substrate 61, a fourth electronic component such as input capacitor 3 and output capacitor 14, and a connection member 62 that connects second substrate 61 and substrate 21.

Second substrate 61 is a circuit board that constitutes a part of power supply circuit 1 together with substrate 21, for example. Second substrate 61 is spaced apart from substrate 21 in first direction DR1. Second substrate 61 is disposed so as not to overlap with first surface 21A and second surface 21B of substrate 21 when viewed from third direction DR3. Second substrate 61 is disposed on a side of power unit 20 opposite to the side thereof where second portion 23B protrudes from first heat radiation member 22.

Second substrate 61 has a sixth surface 61A and a seventh surface 61B located opposite to sixth surface 61A. Input capacitor 3 and output capacitor 14 are mounted on sixth surface 61A. Input capacitor 3 and output capacitor 14 are preferably arranged side by side in second direction DR2. Seventh surface 61B faces substrate 21. Each of sixth surface 61A and seventh surface 61B is orthogonal to first direction DR1, for example. Seventh surface 61B faces substrate 21 in first direction DR1, for example. The dimension of second substrate 61 in third direction DR3 is preferably smaller than the dimension of second substrate 61 in second direction DR2.

Input capacitor 3 and output capacitor 14 are, for example, a film capacitor. The film capacitor includes a polymer film as a dielectric and does not include an electrolytic solution.

Connection member 62 electrically connects wires formed on each of substrate 21 and second substrate 61. Connection member 62 functions as, for example, a fixing member that fixes second substrate 61 to substrate 21. Connection member 62 is, for example, a bus bar.

In the power conversion device according to the sixth embodiment, since input capacitor 3 and output capacitor 14 are mounted on second substrate 61 instead of substrate 21, substrate 21 can be made smaller in third direction DR3 as compared with a power conversion device in which input capacitor 3 and output capacitor 14 are mounted on first surface 21A or second surface 21B of substrate 21.

Particularly, the dimension (height) of a general film capacitor in third direction DR3 is the largest among the electronic components included in the power conversion device. Therefore, in the case where a film capacitor is mounted on substrate 21, it is necessary to increase the distance between substrate 21 and substrate 21 of another power unit 20 in third direction DR3 or the distance between substrate 21 and second heat radiation member 41 of heat radiation unit 40 in third direction DR3. Therefore, the dimension of the power conversion device in which the film capacitor is mounted on substrate 21 increases in third direction DR3.

In contrast, in the power conversion device according to the sixth embodiment, since the film capacitor is mounted on second substrate 61 instead of substrate 21, the entire power conversion device can be made smaller in third direction DR3.

In addition, in the power conversion device according to the sixth embodiment, since a film capacitor can be employed as each of input capacitor 3 and output capacitor 14, a problem that may occur when an electrolytic capacitor is employed as each of input capacitor 3 and output capacitor 14 does not occur. Specifically, in an electrolytic capacitor, a sealing rubber is provided to prevent evaporation and leakage of the electrolytic solution, and a lead terminal of the positive electrode and a lead terminal of the negative electrode are provided to pass through a corresponding opening provided on the sealing rubber. Generally, the sealing rubber is made of an organic material. Therefore, it is known that the deterioration of the sealing rubber proceeds in accordance with Arrhenius's law, and the life of the sealing rubber is reduced by half when the operating temperature rises, for example, by 10° C. When the sealing rubber deteriorates and thereby the electrolytic solution evaporates, the capacitance of the electrolytic capacitor decreases. Therefore, when input capacitor 3 and output capacitor 14 are formed of an electrolytic capacitor, the capacitance of input capacitor 3 and output capacitor 14 decreases, and the function for smoothing the voltage required by input capacitor 3 and output capacitor 14 is impaired, and as a result, the output voltage of power supply circuit 1 may not be controlled to a target value. In contrast, in the power conversion device according to the sixth embodiment, since the film capacitor can be employed as each of input capacitor 3 and output capacitor 14, the function of each of input capacitor 3 and output capacitor 14 does not deteriorate due to evaporation and leakage of the electrolytic solution. The reliability of the power conversion device according to the sixth embodiment is higher than that of a power conversion device in which an electrolytic capacitor is employed as input capacitor 3 and output capacitor 14.

### Modification

In the power conversion device according to the sixth embodiment, second substrate 61 may be a laminate busbar. Input capacitor 3 and output capacitor 14 may be fastened to the laminate busbar by screws, for example. Input capacitor 3 and output capacitor 14 are electrically connected to wiring formed on substrate 21 via the laminate bus bar.

The fourth electronic component mounted on second substrate 61 is not limited to a film capacitor. The fourth electronic component may be any electronic component whose dimension in third direction DR3 is larger than that of the first electronic component.

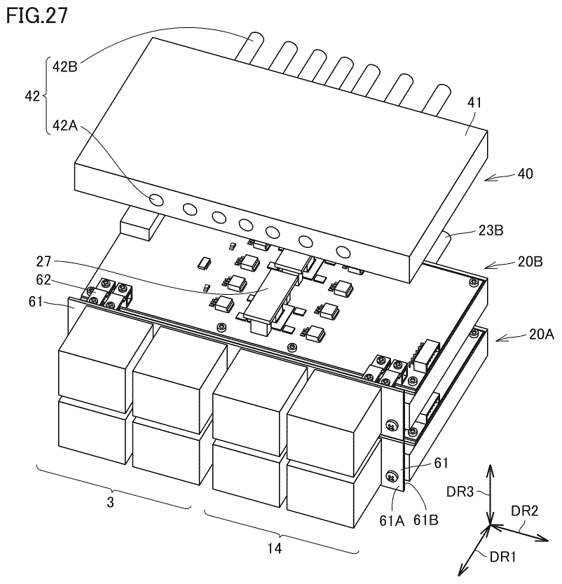

As illustrated in FIG. 27, the power conversion device according to the sixth embodiment may include a plurality of power units 20 and a plurality of second substrates 61. The electronic components included in power supply circuit 1 of each of the plurality of power units 20 are mounted on the plurality of second substrates 61. For example, input capacitor 3 and output capacitor 14 of each power supply circuit 1 are mounted on the plurality of second substrates 61. The dimension of each second substrate 61 in third direction DR3 is preferably smaller than the dimension of each second substrate 61 in second direction DR2.

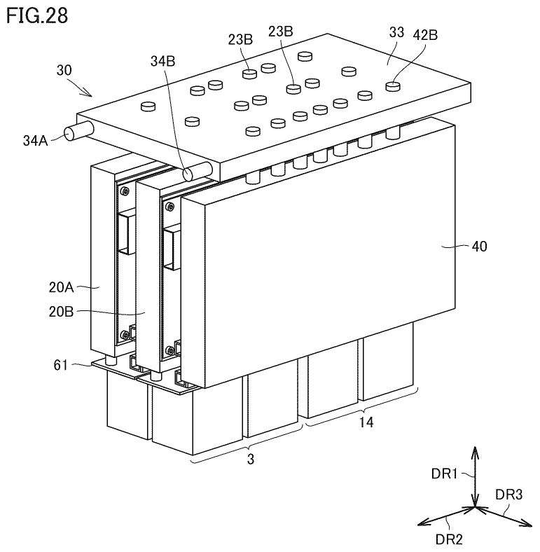

As illustrated in FIG. 28, the power conversion device according to the sixth embodiment may include a cooler 30 which is the same as that of the power conversion device according to the fifth embodiment. Cooling plate 33 of cooler 30 is disposed on one side of each of the plurality of power units 20 in first direction DR1, and plurality of second substrates 61 and input capacitor 3 and output capacitor 14 mounted on each second substrate 61 are disposed on the other side of each of the plurality of power units 20 in first direction DR1.

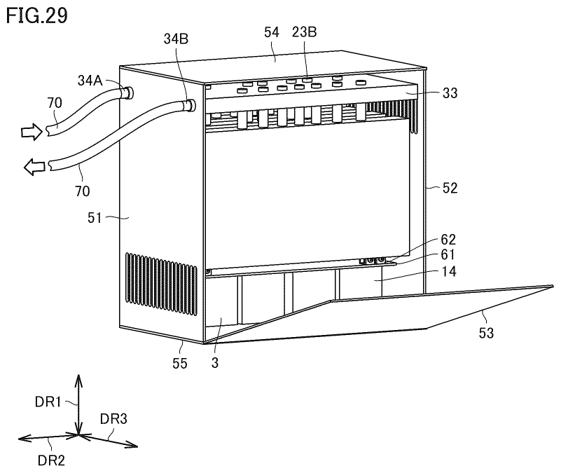

As illustrated in FIG. 29, the power conversion device according to the sixth embodiment may further include a housing 50. Housing 50 may have the same configuration as housing 50 of the power conversion device according to the third embodiment. Each of inflow port 34A and outflow port 34B of tube 34 of cooler 30 protrudes to the outside of housing 50 from, for example, a through hole formed in front plate 51. Each of inflow port 34A and outflow port 34B is connected to one end of the hose 70. For example, second substrate 61 is disposed below the plurality of power units 20, and input capacitor 3 and output capacitor 14 are disposed below second substrate 61.

It should be understood that the embodiments disclosed herein are illustrative and non-restrictive in all respects. The scope of the present invention is defined by the terms of the claims rather than the description of the embodiments above, and is intended to include any modifications within the scope and meaning equivalent to the terms of the claims.

### REFERENCE SIGNS LIST

1: power supply circuit; 2: input terminal; 3: input capacitor; 4: inverter circuit; 5: transformer circuit; 6: rectifier circuit; 7: smoothing circuit; 8: control circuit; 9: output terminal; 10a, 10b, 10c, 10d: switching element; 11a, 11b: transformer; 11b1, 11b2: portion; 12a, 12b, 12c, 12d: rectifier element; 13: smoothing reactor; 14: smoothing capacitor; 15: first wiring pattern; 16: second wiring pattern; 17: ground terminal; 20: power unit; 20A: first power unit; 20B: second power unit; 21: substrate; 21A: first surface; 21B: second surface; 22: first heat radiation member; 22A: third surface; 22B: fourth surface; 22C: first protruding portion; 22D: second protruding portion; 23, 231, 232, 233, 234, 235, 236, 237: first heat transfer member; 23A, 231A, 232A, 233A, 234A, 235A, 236A, 237A: first portion; 23B, 231B: second portion; 24, 26, 27, 28: thermally conductive member; 25: positioning member; 30: cooler; 31: cooling body; 32: fan; 33, 36: cooling plate; 34, 37: tube; 34A: inflow port; 34B: outflow port; 34C: bent portion; 34D: straight tube portion; 34D1: first straight tube portion; 34D2: second straight tube portion; 34D3: third straight tube portion; 40: heat radiation unit; 41: second heat radiation member; 41A: fifth surface; 41C: third protruding portion; 41D: fourth protruding portion; 42, 421, 422: second heat transfer member; 42A, 421A, 422A: third portion; 42B: fourth portion; 56: inlet/outlet port; 50: housing; 51: front plate; 52: back plate; 53: side plate; 54: top plate; 55: bottom plate; 57: opening; 61: second substrate; 61A: sixth surface; 61B: seventh surface; 62: connection member; 70: hose; 111: primary winding; 112: secondary winding; 113: spacer; 114, 115: core; 221: groove; 221A: side surface; 221B: bottom surface.

1. A power conversion device comprising:
at least one power unit,
wherein the at least one power unit includes:
a substrate which has a first surface and a second surface opposite to the first surface;
a first heat radiation member which has a third surface thermally connected to the first surface or the second surface; and
at least one first heat transfer member which includes a first portion disposed inside the first heat radiation member and a second portion connected to the first portion and disposed outside the first heat radiation member, and is configured to transfer heat from the first portion to the second portion,
at least one first electronic component is mounted on at least one of the first surface and the second surface of the substrate,
the at least one first heat transfer member is separated from the first heat radiation member,
the first portion of the at least one first heat transfer member is thermally connected to the at least one first electronic component via the first heat radiation member,
the at least one power unit includes a plurality of power units,
the plurality of power units include a first power unit and a second power unit stacked with the first power unit in a direction orthogonal to the first surface, and
the first heat radiation member of the second power unit includes a fourth surface which is thermally connected to the at least one first component of the first power unit.

2. The power conversion device according to claim 1, wherein, in the first power unit,
the at least one first electronic component includes a plurality of first electronic components arranged side by side in a first direction along the first surface, and
at least a part of the first portion of the at least one first heat transfer member is disposed to extend in the first direction and overlap with the first heat radiation member and each of the plurality of first electronic components in a direction orthogonal to the first surface.

3. The power conversion device according to claim 1, wherein, in the first power unit,
the at least one first electronic component includes a portion disposed on the first surface,
the third surface is formed with a groove,
the third surface of the first heat radiation member is thermally connected to the first surface,
a side surface of the groove is thermally connected to the at least one first electronic component, and
at least a part of the first portion of the at least one first heat transfer member is disposed to extend along the side surface and overlap with the at least one first electronic component and the side surface of the groove in a direction orthogonal to the side surface.

4. The power conversion device according to claim 3, wherein, in the first power unit,
a second electronic component is mounted on the second surface of the substrate, and
at least a part of the first portion of the at least one first heat transfer member is disposed to overlap with the second electronic component in a direction orthogonal to the first surface, and is thermally connected to the second electronic component via the first heat radiation member and the substrate.

5. The power conversion device according to claim 1, wherein, in the first power unit,
the at least one first electronic component includes a portion disposed on the first surface,
the third surface is formed with a groove,
the third surface of the first heat radiation member is thermally connected to the first surface,
a bottom surface of the groove is thermally connected to each of the at least one first electronic component, and
at least a part of the first portion of the at least one first heat transfer member is disposed to extend along the bottom surface and overlap with the at least one first electronic component and the bottom surface of the groove in a direction orthogonal to the bottom surface.

6. The power conversion device according to claim 1, further comprising:
a heat radiation unit,
wherein the heat radiation unit includes:
a second heat radiation member which is thermally connected to the second power unit; and
at least one second heat transfer member which includes a third portion disposed inside the second heat radiation member and a fourth portion connected to the third portion and disposed outside the second heat radiation member, and is configured to transfer heat from the third portion to the fourth portion.

7. (canceled)

8. The power conversion device according to claim 1, wherein
the at least one first electronic component and a third electronic component are mounted on the second surface of the first power unit,
the fourth surface of the first heat radiation member of the second power unit faces the second surface of the first power unit and is thermally connected to the at least one first electronic component of the first power unit, and the first heat radiation member of the second power unit includes a first protruding portion which protrudes from the fourth surface toward the second surface,
a top surface of the first protruding portion is thermally connected to the second surface of the first power unit or the third electronic component, and
in the second power unit, at least a part of the first portion of the at least one first heat transfer member is disposed inside the first protruding portion.

9. The power conversion device according to claim 8, wherein
the first heat radiation member of the second power unit further includes a second protruding portion which protrudes from the fourth surface toward the second surface,
the first protruding portion and the second protruding portion are disposed to sandwich each of the at least one first electronic component in a third direction along the fourth surface, and
a surface region of the fourth surface located between the first protruding portion and the second protruding portion is thermally connected to each of the at least one first electronic component.

10. The power conversion device according to claim 9, further comprising:
a heat radiation unit,
wherein the heat radiation unit includes:
a second heat radiation member which is thermally connected to the at least one power unit; and
a plurality of second heat transfer members, each of which includes a third portion disposed inside the second heat radiation member and a fourth portion connected to the third portion and disposed outside the second heat radiation member, and is configured to transfer heat from the third portion to the fourth portion,
the second heat radiation member includes a fifth surface which faces the second surface of the second power unit and is thermally connected to the at least one first electronic component of the second power unit, and a third protruding portion which protrudes from the fifth surface toward the second surface,
the plurality of second heat transfer members include:
a first second heat transfer member in which at least a part of the third portion is disposed inside the third protruding portion; and
a second heat transfer member in which at least a part of the third portion is disposed to overlap with the at least one first electronic component in a direction orthogonal to the fifth surface.

11. The power conversion device according to claim 71, wherein
a power supply circuit including a transformer is mounted on the substrate,
the power supply circuit includes a primary circuit and a secondary circuit which operates at an operating voltage different from that of the primary circuit and has a ground terminal, and
the first heat radiation member is electrically connected to the ground terminal.

12. The power conversion device according to claim 1, further comprising:
a cooler which cools the second portion of the at least one first heat transfer member.

13. The power conversion device according to claim 12, wherein
the cooler is arranged side by side with the first heat radiation member in a first direction along the first surface.

14. The power conversion device according to claim 12, wherein
the at least one power unit includes a plurality of power units stacked in a direction orthogonal to the first surface,
the first portion of the at least one first heat transfer member of each of the plurality of power units extends along the first surface,
the second portion of the at least one first heat transfer member of each of the plurality of power units extends along a direction intersecting the first surface, and
the cooler cools the second portion of the at least one first heat transfer member of each of the plurality of power units.

15. The power conversion device according to claim 12,
further comprising:
a heat radiation unit,
wherein the heat radiation unit includes:
a second heat radiation member which is thermally connected to the at least one power unit; and
at least one second heat transfer member which includes a third portion disposed inside the second heat radiation member and a fourth portion connected to the third portion and disposed outside the second heat radiation member, and is configured to transfer heat from the third portion to the fourth portion,
the cooler further cools the fourth portion of the at least one second heat transfer member.

16. The power conversion device according to claim 12, wherein,
the cooler includes at least one cooling body which is thermally connected to the second portion of the at least one first heat transfer member and at least one fan which blows air to the at least one cooling body.

17. The power conversion device according to claim 12, wherein
the cooler includes at least one cooling body which is thermally connected to the second portion of the at least one first heat transfer member and at least one tube which is thermally connected to the at least one cooling body.

18. The power conversion device according to claim 17, wherein
the second portion of the at least one first heat transfer member is disposed inside the at least one cooling body, and
the at least one tube has a bent portion arranged around the second portion inside the at least one cooling body.

19. The power conversion device according to claim 18, wherein
the at least one first heat transfer member includes a plurality of first heat transfer members,
the at least one tube includes a first tube portion and a second tube portion connected to each other in series via the bent portion, and
inside the at least one cooling body, the second portion of each of the plurality of first heat transfer members is disposed between the first tube portion and the second tube portion.

20. The power conversion device according to claim 1, wherein
the at least one power unit includes;
a second substrate which has a sixth surface; and
at least one fourth electronic component which is mounted on the sixth surface,
the second substrate and the at least one fourth electronic component are disposed so as not to overlap with the first surface and the second surface of the substrate when viewed from a direction orthogonal to the first surface.

21. A power conversion device comprising:
at least one power unit,
wherein the at least one power unit includes:
a substrate which has a first surface and a second surface opposite to the first surface;
a first heat radiation member which has a third surface thermally connected to the first surface or the second surface; and
at least one first heat transfer member which includes a first portion disposed inside the first heat radiation member and a second portion connected to the first portion and disposed outside the first heat radiation member, and is configured to transfer heat from the first portion to the second portion,
at least one first electronic component is mounted on at least one of the first surface and the second surface of the substrate,
the at least one first heat transfer member is separated from the first heat radiation member,
the first portion of the at least one first heat transfer member is thermally connected to the at least one first electronic component via the first heat radiation member,
the at least one power unit includes;
a second substrate which has a sixth surface; and
at least one fourth electronic component which is mounted on the sixth surface,
the second substrate and the at least one fourth electronic component are disposed so as not to overlap with the first surface and the second surface of the substrate when viewed from a direction orthogonal to the first surface.
